(19) United States
(12) Patent Application Publication
(10) Pub. No.: US 2026/0193781 A1
(43) Pub. Date: Jul. 9, 2026

(54) FLUORINATED METAL-AMIDRAZONIDE COMPLEXES AND METHOD OF USING THE SAME FOR DEPOSITION OF METAL-CONTAINING THIN FILMS

(71) Applicant: L'Air Liquide, Société Anonyme pour l'Etude et l'Exploitation des Procédés Georges Claude, Paris (FR)

(72) Inventors: Luis C. MISAL CASTRO, Yokohama (JP); Jamie GREER, Cologne (DE); Christian DUSSARRAT, Tokyo (JP); Medet ZHUKUSH, Yokosuka (JP)

(21) Appl. No.: 19/009,552

(22) Filed: Jan. 3, 2025

(51) Int. Cl. C23C 16/455; C23C 16/40

(52) U.S. Cl. CPC C23C 16/45553; C23C 16/406

(57) ABSTRACT

A method for forming a metal-containing film on a substrate comprises:
exposing the substrate to a vapor of a metal-containing film-forming composition that contains a fluorinated metal-amidrazonide precursor; and
depositing at least part of the fluorinated metal-amidrazonide precursors onto the substrate to form the metal-containing film on the substrate through a vapor deposition method, wherein the fluorinated metal-amidrazonide precursor having the general formula

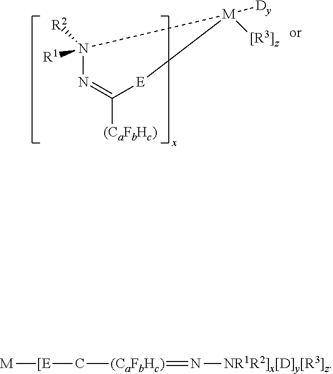

### TECHNICAL FIELD

The present invention relates to metal-containing film-forming compositions comprising fluorinated metal-amidrazonide precursors, methods of synthesizing the fluorinated metal-amidrazonide precursors, and methods of using the same, in particular, to metalated fluorinated amidrazonides that show high volatility for use in deposition of metal-containing films by vapor depositions, especially for use in deposition of metal oxy-fluoride and metal fluoride thin films. The disclosed fluorinated metal-amidrazonide precursors have the general formula

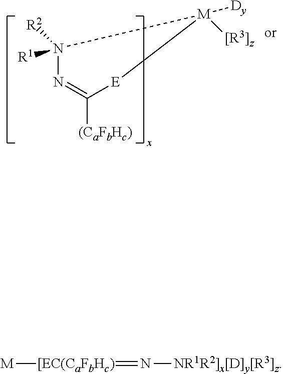

### BACKGROUND

Metal-containing thin films are commonly applied as surface coatings in many applications within electronics, optics, photonics and energy-related fields. Much work has also focused on benefits of fluorine-containing films to these applications in the form of oxyfluoride, fluoride, and/or fluoride-doped films versus their fluorine-free counterparts. Such known examples include YF₃ which has high chemical, thermal and corrosion resistance that makes it useful as a protective layer in semiconductor plasma processing equipment. F-presence may improve ionic conductivity of solid electrolyte interface (SEI) layers that naturally occur at the surface of electrodes in Li-ion batteries, which may benefit charge times, increase charge capacity and boost battery lifetimes. Many fluorides, such as MgF₂ and CaF₂ also have a relatively low refractive index (RI) making them ideal for many optical coating applications.

Current thin-film deposition techniques rely on several solutions to provide adequate fluorine incorporation. The first option relies on depositing films using a standard metal precursor in tandem with fluorine containing co-reactants, such as pyridine-HF (C₅H₆FN), HF, or metal fluorides, such as TiF₄. Issues with this approach are highly corrosive and toxic nature of the co-reactants. Other examples have used reactants such as SF₆ or CF₄ with plasma to provide a source of fluorine; however, issues with these chemicals are their greenhouse gas effect, depleting effect on ozone layers, as well as issues with use of plasma which may lead to poor uniformity on complex 3D structures. More recent alternative methods have described single-source processes wherein fluorine containing metal precursors are used; most often this involves 1,1,1,5,5,5-Hexafluoro-2,4-pentanedione (HFAC) which are often highly volatile and thermally stable. While this is a more simplified & cleaner method, one lasting issue with HFAC compounds is the high thermal stability may lead to poor chemisorption, leading to narrower process windows and poor growth.

Various attempts have been conducted on metal-containing HFAC precursors or organometallic precursors for deposition of metal-containing thin films using chemical vapor deposition (CVD) process.

WO 2010132871 discloses thermally stable volatile film precursors having the formula MₓL_{y} where M is a metal and L is an amidrazone-derived ligand or an amidate-derived ligand.

U.S. Pat. No. 7,985,449 B2 discloses methods for depositing metal films in which the organometallic copper precursors include1,1,1,5,5,5-hexafluoro-2,4-pentanedionato-copper (1) trimethylvinylsilane.

U.S. Pat. No. 7,205,422 discloses volatile metal beta-ketoiminate and metal beta-diiminate complexes having the formula:

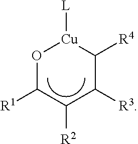

U.S. Pat. No. 4,425,281 discloses copper or silver complexes with fluorinated diketones and unsaturated ligands

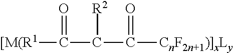

WO 2012074511 discloses deposition of alkaline earth metal fluoride films in gas phase at low temperature in which an alkaline earth metal precursor having the formula MX¹ₒₓ₋ₙX²ₒₓ₋ₘLₚ.

Dear et al. discloses (Inorganic chemistry, (1970), 9(11), 2590-2591) volatile fluorinated alkoxides of the alkali metals.

Jayakodiarachchi at al. discloses (Organometallics 2021, 40, 9, 1270-1283) evaluation of volatility and thermal stability in monomeric and dimeric lanthanide(III) complexes containing enaminolate ligands in which a treatment of 3 equiv of the potassium salts derived from the p-amino ketones 1-(dimethylamino)-3,3-dimethylbutan-2-one (L¹H), 3,3-dimethyl-1-(pyrrolidin-1-yl)butan-2-one (L²H), and 3,3-dimethyl-1-(piperidin-1-yl)butan-2-one (L³H) with anhydrous lanthanide(III) chlorides afforded the complexes Ln(L¹)₃(L¹H) (Ln=Pr, Er, Y), Ln(L¹)₃ (Ln=Pr, Er, Lu, Y), [Nd(L¹)₃]₂, [La(L²)₃]₂, and Ln(L³)₃ (Ln=La, Pr, Nd, Er, Lu, Y) in 30-56% yields after crystallization from a solvent or sublimation.

Pipko et al. (Tetrahedron Lett. 1994, 35, 165-168) discloses structures and properties of phosphorus-containing cations with two intramolecular donor-acceptor bonds N→P. synthesis of the first 5-coordinated p-cation with PN bond, in which reaction with chloramine B or benzenesulphonylazide leads to the formation of first representative of 5-coordinated P-cations with P→N bond.

Van Vliet et al. discloses (Organometallics 1987, 6, 537-546) reactivity of 1-Aza-4-oxa-1,3-butadienes (almino Ketones) toward diorganozinc reagents: regio- and chemoselective transfer of organo groups in the Et₂Zn/R¹NC(R²)—C(R³)O system and x-ray crystal structure of the organozinc enolate [EtZn(Et)(t-Bu)NC(H)C(Me)O]₂.

Cozzi et al. discloses (Organometallics 1994, 13, 1528-1532) β-Keto amino enolates binding to transition metals: synthesis and structure of the ion-pair form and its mono- and bidentate coordination to zirconium and nickel.

Putkonen et al. discloses (J. Mater. Chem., 2011, 21, 14461) ALD of metal fluorides through oxide chemistry.

### SUMMARY

Disclosed is a method for forming a metal-containing film on a substrate, the method comprising:
exposing the substrate to a vapor of a metal-containing film-forming composition that contains a fluorinated metal-amidrazonide precursor; and
depositing at least part of the fluorinated metal-amidrazonide precursors onto the substrate to form the metal-containing film on the substrate through a vapor deposition method,
wherein the fluorinated metal-amidrazonide precursor having the general formula

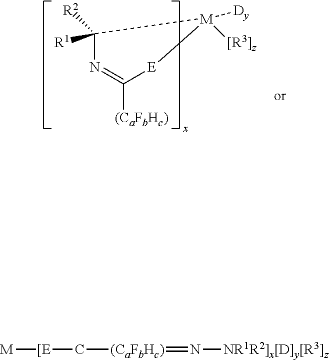

wherein
M is a transition metal or a rare earth element;
E is selected from O, S, Se or Te;
D is a monodentate, bidentate, tridentate, or a polydentate donor with a neutral charge;
CₐF_{b}H_{c} is a fluorinated backbone, wherein a≥1, b≥1, c≥0;
R¹ and R² each are independently selected from an H, a C₁-C₆ linear or branched alkyl group, a C₃-C₆ cyclic alkyl group, a C₂-C₆ linear or branched alkene group, a C₃-C₆ cyclic alkene or aromatic group, wherein any coordinating moieties contain heteroatoms N, O, S;
R³ is selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is from 1 to 5;
y is from 0 to 5; and
z is from 0 to 5.

The disclosed deposition method may include one or more of the following features:
the transition metal being selected from Li, Na, K, Mg, Ca, Sr, Ba, Al, Ga, In, Cu, Mn, Fe, Ni, Co, Ti, Zr, Hf, V, Nb, Ta;
the monodentate, bidentate, tridentate, or a polydentate donor containing heteroatoms N, O, P, or S, or combination thereof;
the monodentate, bidentate, tridentate, or a polydentate donor containing alkenes, alkynes, or carbenes;
the fluorinated metal-amidrazonide precursor being bis(N,N′-dimethyl-trifluoroacetohydrazonide)nickel(II), [Me₂NN═C(CF₃)O]₂Ni;
the fluorinated metal-amidrazonide precursor being [Me₂N—N═C(CF₃)O]AlEt₂;
the fluorinated metal-amidrazonide precursor being [Me₂N—N═C(CF₃)O]₂AlEt;
the fluorinated metal-amidrazonide precursor being [Me₂N—N═C(CF₃)O]₂Cu;
the fluorinated metal-amidrazonide precursor being [Me₂N—N═C(CF₂H)O]₂Cu;
the fluorinated metal-amidrazonide precursor being [Me₂N—N═C(CF₃)O]₂Ni;
the fluorinated metal-amidrazonide precursor being [Me₂N—N═C(CF₂Me)O]₂Ni;
the fluorinated metal-amidrazonide precursor being [Me₂N—N═C(CF₂Me)O]₂Ni;
the fluorinated metal-amidrazonide precursor being Me₂N—N═C(CF₃)O][CH₂C(CH₃)CH₂]Ni;
the fluorinated metal-amidrazonide precursor being Li—OC(CF₃)═N—NMe₂, and Na—OC(CF₃)═N—NMe₂;
the fluorinated metal-amidrazonide precursor being selected from [Me₂N—N═C(CF₃)O]AlEt₂, [Me₂N—N═C(CF₃)O]₂AlEt, [Me₂N—N═C(CF₃)O]₂Cu, [Me₂N—N═C(CF₂H)O]₂Cu, [Me₂N—N═C(CF₃)O]₂Ni, [Me₂N—N═C(CF₂Me)O]₂Ni, [Me₂N—N═C(CF₂Me)O]₂Ni, [Me₂N—N═C(CF₃)O][CH₂C(CH₃)CH₂]Ni, [Me₂N—N═C(CF₂Me)O][CH₂C(CH₃)CH₂]Ni;
the fluorinated metal-amidrazonide precursor being selected from Ni[Me₂N—N═C(CF₃)O]₂, Li—OC(CF₃)═N—NMe₂, and Na—OC(CF₃)═N—NMe₂;
the fluorinated metal-amidrazonide precursor being selected from Cu[Me₂N—N═C(CF₃)O], Ag[Me₂N—N═C(CF₃)O], Au[Me₂N—N═C(CF₃)O], Ag[Me₂N—N═C(CF₂CF₃)O], Cu[MeEtN—N═C(CF₃)O], Ag[MeEtN—N═C(CF₃)O], Au[MeEtN—N═C(CF₃)O], Ag[MeEtN—N═C(CF₂CF₃)O], tmsv·Cu[Me₂N—N═C(CF₃)O], tmsv·Ag[Me₂N—N═C(CF₃)O], tmsv·Au[Me₂N—N═C(CF₃)O], tmsv·Ag[Me₂N—N═C(CF₂CF₃)O], tmsv·Cu[MeEtN—N═C(CF₃)O], tmsv·Ag[MeEtN—N═C(CF₃)O], tmsv·Au[MeEtN—N═C(CF₃)O], tmsv·Ag[MeEtN—N═C(CF₂CF₃)O], tmsv·Cu[Me₂N—N═C(CF₃)O]₂, (Me₃Si)₂-acetylene·Cu[Me₂N—N═C(CF₃)O], (Me₃Si)₂-acetylene·Ag[Me₂N—N═C(CF₃)O], (Me₃Si)₂-acetylene·Au[Me₂N—N═C(CF₃)O], (Me₃Si)₂-acetylene·Ag[Me₂N—N═C(CF₂CF₃)O], (Me₃Si)₂-acetylene·Cu[MeEtN—N═C(CF₃)O], (Me₃Si)₂-acetylene·Ag[MeEtN—N═C(CF₃)O], (Me₃Si)₂-acetylene·Au[MeEtN—N═C(CF₃)O], (Me₃Si)₂-acetylene·Ag[MeEtN—N═C(CF₂CF₃)O], (Me₃Si)₂-acetylene·Cu[Me₂N—N═C(CF₃)O]₂, Me₃P·Cu[Me₂N—N═C(CF₃)O], Me₃P·Ag[Me₂N—N═C(CF₃)O], Me₃P·Au[Me₂N—N═C(CF₃)O], Me₃P·Ag[Me₂N—N═C(CF₂CF₃)O], Me₃P·Cu[MeEtN—N═C(CF₃)O], Me₃P·Ag[MeEtN—N═C(CF₃)O], Me₃P·Au[MeEtN—N═C(CF₃)O], Me₃P·Ag[MeEtN—N═C(CF₂CF₃)O], Me₃P·Cu[Me₂N—N═C(CF₃)O]₂, Et₃P·Cu[Me₂N—N═C(CF₃)O], Et₃P·Ag[Me₂N—N═C(CF₃)O], Et₃P·Au[Me₂N—N═C(CF₃)O], Et₃P·Ag[Me₂N—N═C(CF₂CF₃)O], Et₃P·Cu[MeEtN—N═C(CF₃)O], Et₃P·Ag[MeEtN—N═C(CF₃)O], Et₃P·Au[MeEtN—N═C(CF₃)O], Et₃P·Ag[MeEtN—N═C(CF₂CF₃)O], Et₃P·Cu[Me₂N—N═C(CF₃)O]₂, (MeO)₃P·Cu[Me₂N—N═C(CF₃)O], (MeO)₃P·Ag[Me₂N—N═C(CF₃)O], (MeO)₃P·Au[Me₂N—N═C(CF₃)O], (MeO)₃P·Ag[Me₂N—N═C(CF₂CF₃)O], (MeO)₃P·Cu[MeEtN—N═C(CF₃)O], (MeO)₃P·Ag[MeEtN—N═C(CF₃)O], (MeO)₃P·Au[MeEtN—N═C(CF₃)O], (MeO)₃P·Ag[MeEtN—N═C(CF₂CF₃)O], (MeO)₃P·Cu[Me₂N—N═C(CF₃)O]₂, Mn[Me₂N—N═C(CF₃)O]₂, Ca[Me₂N—N═C(CF₃)O]₂, Mg[Me₂N—N═C(CF₃)O]₂, Co[Me₂N—N═C(CF₃)O]₂, Sr[Me₂N—N═C(CF₃)O]₂, Zn[Me₂N—N═C(CF₃)O]₂, Cr[Me₂N—N═C(CF₃)O]₂, Ti[Me₂N—N═C(CF₃)O]₂, Cu[MeEtN—N═C(CF₃)O]₂, Mn[MeEtN—N═C(CF₃)O]₂, Ca[MeEtN—N═C(CF₃)O]₂, Mg[MeEtN—N═C(CF₃)O]₂, Co[MeEtN—N═C(CF₃)O]₂, Sr[MeEtN—N═C(CF₃)O]₂, Ni[MeEtN—N═C(CF₃)O]₂, Zn[MeEtN—N═C(CF₃)O]₂, Cr[MeEtN—N═C(CF₃)O]₂, Ti[MeEtN—N═C(CF₃)O]₂, AI[Me₂N—N═C(CF₃)O]₃, Ga[Me₂N—N═C(CF₃)O]₃, In[Me₂N—N═C(CF₃)O]₃, Ti[Me₂N—N═C(CF₃)O]₃, Sc[Me₂N—N═C(CF₃)O]₃, CpTi[Me₂N—N═C(CF₃)O]₂, CpZr[Me₂N—N═C(CF₃)O]₂, CpHf[Me₂N—N═C(CF₃)O]₂, CpV[Me₂N—N═C(CF₃)O]₂, CpSc[Me₂N—N═C(CF₃)O]₂, CpCe[Me₂N—N═C(CF₃)O]₂, CpY[Me₂N—N═C(CF₃)O]₂, CpLa[Me₂N—N═C(CF₃)O]₂, EtAI[Me₂N—N═C(CF₃)O]₂, EtGa[Me₂N—N═C(CF₃)O]₂, EtIn[Me₂N—N═C(CF₃)O]₂, MeAl[Me₂N—N═C(CF₃)O]₂, MeGa[Me₂N—N═C(CF₃)O]₂, MeIn[Me₂N—N═C(CF₃)O]₂, sBuAl[Me₂N—N═C(CF₃)O]₂, sBuGa[Me₂N—N═C(CF₃)O]₂, sBuIn[Me₂N—N═C(CF₃)O]₂, iPrAl[Me₂N—N═C(CF₃)O]₂, iPrGa[Me₂N—N═C(CF₃)O]₂, iPrIn[Me₂N—N═C(CF₃)O]₂, Cp₂Ti[Me₂N—N═C(CF₃)O]₂, Cp₂Zr[Me₂N—N═C(CF₃)O]₂, Cp₂Hf[Me₂N—N═C(CF₃)O]₂, EtCp₂Ti[Me₂N—N═C(CF₃)O]₂, EtCp₂Zr[Me₂N—N═C(CF₃)O]₂, EtCp₂Hf[Me₂N—N═C(CF₃)O]₂, MeCp₂Ti[Me₂N—N═C(CF₃)O]₂, MeCp₂Zr[Me₂N—N═C(CF₃)O]₂, MeCp₂Hf[Me₂N—N═C(CF₃)O]₂, iPrCp₂Ti[Me₂N—N═C(CF₃)O]₂, iPrCp₂Zr[Me₂N—N═C(CF₃)O]₂, iPrCp₂Hf[Me₂N—N═C(CF₃)O]₂, CpTi[Me₂N—N═C(CF₃)O]₃, CpZr[Me₂N—N═C(CF₃)O]₃, CpHf[Me₂N—N═C(CF₃)O]₃, EtCpTi[Me₂N—N═C(CF₃)O]₃, EtCpZr[Me₂N—N═C(CF₃)O]₃, EtCpHf[Me₂N—N═C(CF₃)O]₃, MeCpTi[Me₂N—N═C(CF₃)O]₃, MeCpZr[Me₂N—N═C(CF₃)O]₃, MeCpHf[Me₂N—N═C(CF₃)O]₃, iPrCpTi[Me₂N—N═C(CF₃)O]₃, iPrCpZr[Me₂N—N═C(CF₃)O]₃, or iPrCpHf[Me₂N—N═C(CF₃)O]₃;
the vapor deposition method being a CVD process;
the vapor deposition method being an ALD process;
a deposition temperature ranging from approximately 50° C. to approximately 600° C.;
a deposition temperature ranging from approximately 50° C. to approximately 600° C. when a plasma deposition process is utilized;
a deposition temperature ranging from approximately 100° C. to approximately 600° C. when a thermal process is applied;
a deposition temperature being 300° C.;
the co-reactant being plasma activated;
the co-reactant being not plasma activated;
the co-reactant being an oxygen-containing gas selected from O₂, O₃, H₂O, H₂O₂, NO, N₂O, NO₂, oxygen containing radicals selected from O— or OH—, alcohol, silanols, aminoalcohols, carboxylic acids, para-formaldehyde, carboxylic acids, formic acid, acetic acid, propionic acid, and mixtures thereof;
the co-reactant being a nitrogen-containing gas selected from H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof;
the co-reactant being O₃;
the co-reactant being at least one secondary precursor selected from silanes and polysilanes, alkylsilanes, halosilanes selected from monochlorosilane (MCS, SiH₃Cl), dichlorosilane (DCS, SiH₂Cl₂), trichlorosilane (TCS, SiHCl₃), or silicon tetrachloride (STC, SiCl₄), polyhalopolysilanes, germane, chlorogermane, digermane, polygermanes, halogermanes, phosphines, boranes or halide containing gases;
the co-reactant being a dilution gas selected from Ar, He, N₂, H₂ or combinations thereof;
the metal-containing film being a metal oxide film;
the metal-containing film being a fluorine-doped nickel oxide;
The substrate being a Si substrate;
the substrate being a powder; and
the powder comprising one or more of NMC (Lithium Nickel Manganese Cobalt Oxide), LCO (Lithium Cobalt Oxide), LFP (Lithium Iron Phosphate), and other battery cathode materials.

Disclosed is a method for forming a fluorine-doped nickel oxide film on a substrate, the method comprising:
exposing the substrate to a vapor of a metal-containing film-forming composition that contains a fluorinated metal-amidrazonide precursor bis(N,N′-dimethyl-trifluoroacetohydrazonide)nickel(II) [Me₂NN═C(CF₃)O]₂Ni; and
depositing at least part of the fluorinated metal-amidrazonide precursors onto the substrate to form the fluorine-doped nickel oxide film on the substrate through a vapor deposition method. The disclosed deposition method may include one or more of the following features:
further comprising the step of exposing the substrate to a co-reactant O₃; and
the co-reactant being either plasma activated or not plasma activated.

Disclosed is a film-forming composition for deposition of a film comprising a fluorinated metal-amidrazonide precursor having the general formula

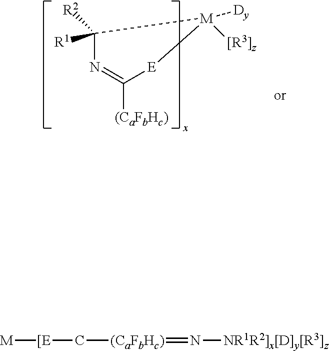

wherein
M is a transition metal or a rare earth element;
E is selected from O, S, Se or Te;
D is a monodentate, bidentate, tridentate, or other polydentate donor with a neutral charge;
CₐF_{b}H_{c} is a fluorinated backbone, wherein a≥1, b≥1, c≥0;
R¹ and R² each is independently selected from an H, a C₁-C₆ linear or branched alkyl group, a C₃-C₆ cyclic alkyl group, a C₂-C₆ linear or branched alkene group, a C₃-C₆ cyclic alkene or aromatic group, wherein any coordinating moieties contain heteroatoms N, O, S;
R³ is selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is from 1 to 5;
y is from 0 to 5; and
z is from 0 to 5. The disclosed deposition method may include one or more of the following features:
the fluorinated metal-amidrazonide precursor being bis(N,N′-dimethyl-trifluoroacetohydrazonide)nickel(II), [Me₂NN═C(CF₃)O]₂Ni;
the fluorinated metal-amidrazonide precursor being [Me₂N—N═C(CF₃)O]AlEt₂;
the fluorinated metal-amidrazonide precursor being [Me₂N—N═C(CF₃)O]₂AlEt;
the fluorinated metal-amidrazonide precursor being [Me₂N—N═C(CF₃)O]₂Cu;
the fluorinated metal-amidrazonide precursor being [Me₂N—N═C(CF₂H)O]₂Cu;
the fluorinated metal-amidrazonide precursor being [Me₂N—N═C(CF₃)O]₂Ni;
the fluorinated metal-amidrazonide precursor being [Me₂N—N═C(CF₂Me)O]₂Ni;
the fluorinated metal-amidrazonide precursor being [Me₂N—N═C(CF₂Me)O]₂Ni;
the fluorinated metal-amidrazonide precursor being Me₂N—N═C(CF₃)O][CH₂C(CH₃)CH₂]Ni;
the fluorinated metal-amidrazonide precursor being Li—OC(CF₃)═N—NMe₂, and Na—OC(CF₃)═N—NMe₂;
the fluorinated metal-amidrazonide precursor being selected from Cu[Me₂N—N═C(CF₃)O], Ag[Me₂N—N═C(CF₃)O], Au[Me₂N—N═C(CF₃)O], Ag[Me₂N—N═C(CF₂CF₃)O], Cu[MeEtN—N═C(CF₃)O], Ag[MeEtN—N═C(CF₃)O], Au[MeEtN—N═C(CF₃)O], Ag[MeEtN—N═C(CF₂CF₃)O], tmsv·Cu[Me₂N—N═C(CF₃)O], tmsv·Ag[Me₂N—N═C(CF₃)O], tmsv·Au[Me₂N—N═C(CF₃)O], tmsv·Ag[Me₂N—N═C(CF₂CF₃)O], tmsv·Cu[MeEtN—N═C(CF₃)O], tmsv·Ag[MeEtN—N═C(CF₃)O], tmsv·Au[MeEtN—N═C(CF₃)O], tmsv·Ag[MeEtN—N═C(CF₂CF₃)O], tmsv·Cu[Me₂N—N═C(CF₃)O]₂, (Me₃Si)₂-acetylene·Cu[Me₂N—N═C(CF₃)O], (Me₃Si)₂-acetylene·Ag[Me₂N—N═C(CF₃)O], (Me₃Si)₂-acetylene·Au[Me₂N—N═C(CF₃)O], (Me₃Si)₂-acetylene·Ag[Me₂N—N═C(CF₂CF₃)O], (Me₃Si)₂-acetylene·Cu[MeEtN—N═C(CF₃)O], (Me₃Si)₂-acetylene·Ag[MeEtN—N═C(CF₃)O], (Me₃Si)₂-acetylene·Au[MeEtN—N═C(CF₃)O], (Me₃Si)₂-acetylene·Ag[MeEtN—N═C(CF₂CF₃)O], (Me₃Si)₂-acetylene·Cu[Me₂N—N═C(CF₃)O]₂, Me₃P·Cu[Me₂N—N═C(CF₃)O], Me₃P·Ag[Me₂N—N═C(CF₃)O], Me₃P·Au[Me₂N—N═C(CF₃)O], Me₃P·Ag[Me₂N—N═C(CF₂CF₃)O], Me₃P·Cu[MeEtN—N═C(CF₃)O], Me₃P·Ag[MeEtN—N═C(CF₃)O], Me₃P·Au[MeEtN—N═C(CF₃)O], Me₃P·Ag[MeEtN—N═C(CF₂CF₃)O], Me₃P·Cu[Me₂N—N═C(CF₃)O]₂, Et₃P·Cu[Me₂N—N═C(CF₃)O], Et₃P·Ag[Me₂N—N═C(CF₃)O], Et₃P·Au[Me₂N—N═C(CF₃)O], Et₃P·Ag[Me₂N—N═C(CF₂CF₃)O], Et₃P·Cu[MeEtN—N═C(CF₃)O], Et₃P·Ag[MeEtN—N═C(CF₃)O], Et₃P·Au[MeEtN—N═C(CF₃)O], Et₃P·Ag[MeEtN—N═C(CF₂CF₃)O], Et₃P·Cu[Me₂N—N═C(CF₃)O]₂, (MeO)₃P·Cu[Me₂N—N═C(CF₃)O], (MeO)₃P·Ag[Me₂N—N═C(CF₃)O], (MeO)₃P·Au[Me₂N—N═C(CF₃)O], (MeO)₃P·Ag[Me₂N—N═C(CF₂CF₃)O], (MeO)₃P·Cu[MeEtN—N═C(CF₃)O], (MeO)₃P·Ag[MeEtN—N═C(CF₃)O], (MeO)₃P·Au[MeEtN—N═C(CF₃)O], (MeO)₃P·Ag[MeEtN—N═C(CF₂CF₃)O], (MeO)₃P·Cu[Me₂N—N═C(CF₃)O]₂, Mn[Me₂N—N═C(CF₃)O]₂, Ca[Me₂N—N═C(CF₃)O]₂, Mg[Me₂N—N═C(CF₃)O]₂, Co[Me₂N—N═C(CF₃)O]₂, Sr[Me₂N—N═C(CF₃)O]₂, Zn[Me₂N—N═C(CF₃)O]₂, Cr[Me₂N—N═C(CF₃)O]₂, Ti[Me₂N—N═C(CF₃)O]₂, Cu[MeEtN—N═C(CF₃)O]₂, Mn[MeEtN—N═C(CF₃)O]₂, Ca[MeEtN—N═C(CF₃)O]₂, Mg[MeEtN—N═C(CF₃)O]₂, Co[MeEtN—N═C(CF₃)O]₂, Sr[MeEtN—N═C(CF₃)O]₂, Ni[MeEtN—N═C(CF₃)O]₂, Zn[MeEtN—N═C(CF₃)O]₂, Cr[MeEtN—N═C(CF₃)O]₂, Ti[MeEtN—N═C(CF₃)O]₂, AI[Me₂N—N═C(CF₃)O]₃, Ga[Me₂N—N═C(CF₃)O]₃, In[Me₂N—N═C(CF₃)O]₃, Ti[Me₂N—N═C(CF₃)O]₃, Sc[Me₂N—N═C(CF₃)O]₃, CpTi[Me₂N—N═C(CF₃)O]₂, CpZr[Me₂N—N═C(CF₃)O]₂, CpHf[Me₂N—N═C(CF₃)O]₂, CpV[Me₂N—N═C(CF₃)O]₂, CpSc[Me₂N—N═C(CF₃)O]₂, CpCe[Me₂N—N═C(CF₃)O]₂, CpY[Me₂N—N═C(CF₃)O]₂, CpLa[Me₂N—N═C(CF₃)O]₂, EtAI[Me₂N—N═C(CF₃)O]₂, EtGa[Me₂N—N═C(CF₃)O]₂, EtIn[Me₂N—N═C(CF₃)O]₂, MeAl[Me₂N—N═C(CF₃)O]₂, MeGa[Me₂N—N═C(CF₃)O]₂, MeIn[Me₂N—N═C(CF₃)O]₂, sBuAl[Me₂N—N═C(CF₃)O]₂, sBuGa[Me₂N—N═C(CF₃)O]₂, sBuIn[Me₂N—N═C(CF₃)O]₂, iPrAl[Me₂N—N═C(CF₃)O]₂, iPrGa[Me₂N—N═C(CF₃)O]₂, iPrIn[Me₂N—N═C(CF₃)O]₂, Cp₂Ti[Me₂N—N═C(CF₃)O]₂, Cp₂Zr[Me₂N—N═C(CF₃)O]₂, Cp₂Hf[Me₂N—N═C(CF₃)O]₂, EtCp₂Ti[Me₂N—N═C(CF₃)O]₂, EtCp₂Zr[Me₂N—N═C(CF₃)O]₂, EtCp₂Hf[Me₂N—N═C(CF₃)O]₂, MeCp₂Ti[Me₂N—N═C(CF₃)O]₂, MeCp₂Zr[Me₂N—N═C(CF₃)O]₂, MeCp₂Hf[Me₂N—N═C(CF₃)O]₂, iPrCp₂Ti[Me₂N—N═C(CF₃)O]₂, iPrCp₂Zr[Me₂N—N═C(CF₃)O]₂, iPrCp₂Hf[Me₂N—N═C(CF₃)O]₂, CpTi[Me₂N—N═C(CF₃)O]₃, CpZr[Me₂N—N═C(CF₃)O]₃, CpHf[Me₂N—N═C(CF₃)O]₃, EtCpTi[Me₂N—N═C(CF₃)O]₃, EtCpZr[Me₂N—N═C(CF₃)O]₃, EtCpHf[Me₂N—N═C(CF₃)O]₃, MeCpTi[Me₂N—N═C(CF₃)O]₃, MeCpZr[Me₂N—N═C(CF₃)O]₃, MeCpHf[Me₂N—N═C(CF₃)O]₃, iPrCpTi[Me₂N—N═C(CF₃)O]₃, iPrCpZr[Me₂N—N═C(CF₃)O]₃, or iPrCpHf[Me₂N—N═C(CF₃)O]₃; and
the monodentate, bidentate, tridentate, or a polydentate donor containing heteroatoms N, O, P, or S, or combination thereof;
the monodentate, bidentate, tridentate, or a polydentate donor containing alkenes, alkynes, or carbenes; and
a purity of the fluorinated metal-amidrazonide precursor is >98%.

### Notation and Nomenclature

The following detailed description and claims utilize a number of abbreviations, symbols, and terms, which are generally well known in the art. Certain abbreviations, symbols, and terms are used throughout the following description and claims, and include:

As used herein, the indefinite article “a” or “an” means one or more.

As used herein, “about” or “around” or “approximately” in the text or in a claim means±10% of the value stated.

As used herein, “room temperature” in the text or in a claim means from approximately 20° C. to approximately 25° C.

The term “ambient temperature” refers to an environment temperature approximately 20° C. to approximately 25° C.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

Note that herein, the terms “deposition temperature” and “substrate temperature” may be used interchangeably. It is understood that a substrate temperature may correspond to, or be related to a deposition temperature, and that the deposition temperature may refer to the substrate temperature.

Please note that the films or layers deposited, such as silicon oxide or silicon nitride, may be listed throughout the specification and claims without reference to their proper stoichiometry (i.e., SiO, SiO₂, SiO₃, Si₃N₄). The layers may include oxide (SiₙOₘ) layers, or mixtures thereof, wherein m and n inclusively range from 1 to 6. For instance, silicon oxide is SiₙOₘ, wherein n ranges from 0.5 to 1.5 and m ranges from 1.5 to 3.5. More preferably, the silicon oxide layer is SiO or SiO₂. The silicon oxide layer may be a silicon oxide based dielectric material, such as organic based or silicon oxide based low-k dielectric materials such as the Black Diamond II or III material by Applied Materials, Inc. with a formula of SiOCH. Alternatively, any referenced silicon-containing layer may be pure silicon. Silicon-containing film may also include SiₐO_{b}C_{c}N_{d}Hₑ where a, b, c, d, e range from 0.1 to 6 and b, c, d, e each may be independently 0. Alternatively, any silicon-containing layers may also include dopants, such as B, C, P, As and/or Ge.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. Examples of suitable substrates include wafers, such as silicon, silica, glass, or GaAs wafers. The substrate may also have one or more layers of differing materials already deposited upon it from a previous manufacturing steps, including silicon-containing films or layers. Examples of suitable layers include without limitation silicon (such as amorphous silicon, p-Si, crystalline silicon, any of which may further be p-doped or n-doped with B, C, P, As, and/or Ge), silica, silicon nitride, silicon oxide, silicon oxynitride, SiₐO_{b}H_{c}C_{d}Nₑ, (wherein a>0; b, c, d, e 0), mask layer materials such as amorphous carbon, antireflective coatings, photoresist materials, tungsten, titanium nitride, tantalum nitride or combinations thereof, etch stop layer materials such as silicon nitride, polysilicon, crystalline silicon, silicon carbide, SiCN or combinations thereof, device channel materials such crystalline silicon, epitaxial silicon, doped silicon, SiₐO_{b}H_{c}C_{d}Nₑ, (wherein a>0; b, c, d, e 0) or combinations thereof. The silicon oxide layer may form a dielectric material, such as an organic based or silicon oxide based low-k dielectric material (e.g., a porous SiCOH film). For example, the substrates may include silicon layers (e.g., crystalline, amorphous, porous, etc.), silicon-containing layers (e.g., SiO₂, SiN, SiON, SiC, SiCN, SiOCN, SiCOH, etc.), metal-containing layers (e.g., copper, cobalt, ruthenium, tungsten, manganese, platinum, palladium, nickel, ruthenium, gold, etc.) or combinations thereof. An exemplary low-k dielectric material is sold by Applied Materials under the trade name Black Diamond II or Ill. Additionally, layers comprising tungsten or noble metals (e.g. platinum, palladium, rhodium or gold) may be used. Furthermore, examples of the silicon-containing films may be SiₐO_{b}H_{c}C_{d}Nₑ, (wherein a>0; b, c, d, e 0). Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

The term “deposits” refers to films, layers, continuous, partially continuous, non-continuous deposited materials, or dots.

The term “wafer”, “patterned wafer” or “workpiece” refers to a wafer having a stack of films on a substrate and at least the top-most film having topographic features that have been created in steps prior to the deposition of the indium containing film. The “wafer” or “patterned wafer” refers to a wafer having a stack of films on a substrate and a patterned hardmask layer on the stack of the films formed for pattern etch.

The term “processing” as used herein includes patterning, exposure, development, etching, deposition, cleaning, and/or removal of by-products, as required in forming a described structure.

The term “mask” refers to a layer that resists etching. The mask layer may be located above the layer to be etched. The mask layer also refers to a hardmask layer.

The term “aspect ratio” refers to a ratio of the height of a trench (or aperture) to the width of the trench (or the diameter of the aperture).

The term “high aspect ratio (HAR)” refers to an aspect ratio ranging from approximately 1:1 to approximately 500:1, preferably from approximately 20:1 to approximately 400:1.

Note that herein, the terms “aperture”, “via”, “hole”, “trench” and “structure” may be used interchangeably, and generally mean an opening formed in a semiconductor structure and/or in an interlayer insulator.

The terms “dope” or “doping” is used interchangeably to the process of incorporation of one or more elements into a film through various methods where that element may be chemically bond or physically bond, and the process of intentionally incorporating atoms of different elements into the film composition. The element(s) may be doped interstitial or substitutional within the film.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

As used herein, the term “formulation” refers to a polymer solution comprising of an oligocarbosilazane, polycarbosilazane, polysilazane, polycarbosilane and polysilane in a solvent.

As used herein, the term “film-forming composition” refers to a mixture of components used for deposition that may contain precursors, catalysts, surfactants, wetting agents, and other polymers, oligomers or monomers such as, but is not limited to, polysilazane, polycarbosilanes, polysilanes, etc.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “hydrofluorocarbon” refers to a saturated or unsaturated function group containing exclusively carbon, fluoride and hydrogen atoms.

As used herein, the term “fluorocarbon” refers to a saturated or unsaturated function group containing exclusively fluoride and hydrogen atoms.

As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to any propyl group (i.e., n-propyl or isopropyl); the abbreviation “iPr” refers to an isopropyl group; the abbreviation “Bu” refers to any butyl group (n-butyl, iso-butyl, tert-butyl, sec-butyl); the abbreviation “tBu” refers to a tert-butyl group; the abbreviation “sBu” refers to a sec-butyl group; the abbreviation “iBu” refers to an iso-butyl group; the abbreviation “Ph” refers to a phenyl group; the abbreviation “Am” refers to any amyl group (iso-amyl, sec-amyl, tert-amyl); the abbreviation “Cy” refers to a cyclic hydrocarbon group (cyclobutyl, cyclopentyl, cyclohexyl, etc.); the abbreviation “Ar” refers to an aromatic hydrocarbon group (phenyl, xylyl, mesityl, etc.).

As used herein, the fluorinated metal-amidrazonide precursor has the general formula

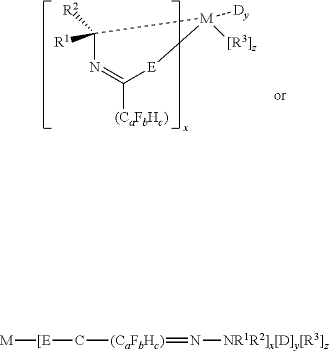

wherein
M is a transition metal or a rare earth element;
E is selected from O, S, Se or Te;
D is a monodentate, bidentate, tridentate, or a polydentate donor with a neutral charge;
CₐF_{b}H_{c} is a fluorinated backbone, wherein a≥1, b≥1, c≥0;
R¹ and R² each are independently selected from an H, a C₁-C₆ linear or branched alkyl group, a C₃-C₆ cyclic alkyl group, a C₂-C₆ linear or branched alkene group, a C₃-C₆ cyclic alkene or aromatic group, wherein any coordinating moieties contain heteroatoms N, O, S;
R³ is selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is from 1 to 5;
y is from 0 to 5; and
z is from 0 to 5.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where M is an atom, x is 2 or 3, the two or three R¹ groups may, but need not be identical to each other or to R² or to R³. Further, it should be understood that unless specifically stated otherwise, values of R groups are independent of each other when used in different formulas.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Optional or optionally means that the subsequently described event or circumstances may or may not occur. The description includes instances where the event or circumstance occurs and instances where it does not occur.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term that means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is a graph of the thermogravimetric analysis (TGA, 760 Torr) of [Me₂N—N═C(CF₃)O]AlEt₂ illustrating the weight loss vs. temperature in conditions representative of delivery conditions (10° C./min);

FIG. 2 is a graph of the TGA at 760 Torr of [Me₂N—N═C(CF₃)O]₂AlEt illustrating the weight loss vs. temperature in conditions representative of delivery conditions (10° C./min);

FIG. 3 is a graph of the TGA at 760 Torr of [Me₂N—N═C(CF₃)O]₂Cu illustrating the weight loss vs. temperature in conditions representative of delivery conditions (10° C./min);

FIG. 4 is a graph of the TGA at 760 Torr (atm) and 15 Torr (vac)] of [Me₂N—N═C(CF₂H)O]₂Cu illustrating the weight loss vs. temperature in conditions representative of delivery conditions (10° C./min);

FIG. 5 is a graph of the TGA at 760 Torr of [Me₂N—N═C(CF₃)O]₂Ni illustrating the weight loss vs. temperature in conditions representative of delivery conditions (10° C./min);

FIG. 6 is a graph of the TGA at 760 Torr of [Me₂N—N═C(CF₂H)O]₂Ni illustrating the weight loss vs. temperature in conditions representative of delivery conditions (10° C./min);

FIG. 7 is a graph of the TGA at 760 Torr of [Me₂N—N═C(CF₂Me)O]₂Ni illustrating the weight loss vs. temperature in conditions representative of delivery conditions (10° C./min).

FIG. 8 is a graph of the TGA at 760 Torr of [Me₂N—N═C(CF₃)O][CH₂C(CH₃)CH₂]Ni illustrating the weight loss vs. temperature in conditions representative of delivery conditions (10° C./min);

FIG. 9 is a graph of the TGA at 760 Torr (atm) and 15 torr (vac)] of [Me₂N—N═C(CF₂Me)O][CH₂C(CH₃)CH₂]Ni illustrating the weight loss vs. temperature in conditions representative of delivery conditions (10° C./min);

FIG. 10 is XPS analysis of the fluorine-doped nickel oxide film over Si wafer formed using [Me₂NN═C(CF₃)O]₂Ni; and

FIG. 11 is SEM analysis of the fluorine-doped nickel oxide film over Si wafer formed using [Me₂NN═C(CF₃)O]₂Ni.

### DESCRIPTION OF PREFERRED EMBODIMENTS

Disclosed are metal-containing film-forming compositions comprising fluorinated metal-amidrazonide precursors, methods of synthesizing the fluorinated metal-amidrazonide precursors, and methods of forming metal-containing films via chemical vapor deposition (CVD) processes using the metal-containing film-forming compositions. More specifically, the disclosed are new metalated fluorinated amidrazonides that show high volatility for use in deposition of metal-containing films by chemical deposition methods, such as CVD, ALD, or the like, especially for use in deposition of metal oxy-fluoride and metal fluoride thin films, as an alternative to metal-1,1,1,5,5,5-Hexafluoro-2,4-pentanedione (metal-HFAC) and metal-HFAC related processes which by comparison show low reactivity.

The disclosed metal fluorinated amidrazonides (where metals are preferably, but not limited to, alkali, alkaline earth, transition metals, p-block metals or rare earth metals) may be used in the same logic for the deposition of metal oxyfluorides and metal fluoride(s). In addition, the disclosed metal fluorinated amidrazonides shows novel, silicon-free, fluorine containing precursors for the formation of metal-containing, metal-fluoride and/or metal-oxyfluoride thin films. The disclosed precursors possess high volatility, with vapor pressures of 1 Torr observed at 120° C., or less, making the metal fluorinated amidrazonides ideal for application in ALD/CVD. By including F in the ligand backbone of the metal fluorinated amidrazonides, stabilization of UV-sensitive elements, such as silver, is also possible.

The disclosed is a new class of fluorinated ligands available to overcome some of the weaknesses in HFAC chemistry, as well as provide a new class of ligands suitable for stabilizing light sensitive metals, such as silver I complexes.

The disclosed fluorinated metal-amidrazonide precursors have the general formula

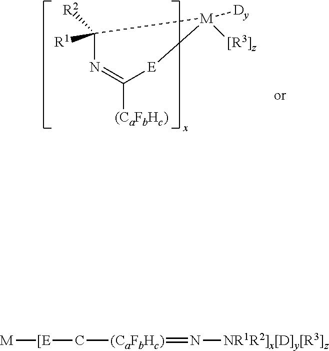

wherein
M is a transition metal or a rare earth element;
E is selected from O, S, Se or Te;
D is independently selected from a neutral ligand independently selected from a monodentate, bidentate, tridentate, or other polydentate donor with a neutral charge, preferably using heteroatoms N, O, P, or S, or combination thereof, donors containing alkenes, or alkynes, or Carbenes;
CₐF_{b}H_{c} is a fluorinated backbone, wherein a≥1, b≥1, c≥0;
R¹ and R² each is independently selected from an H, a C₁-C₆ linear or branched alkyl group, a C₃-C₆ cyclic alkyl group, a C₂-C₆ linear or branched alkene group, a C₃-C₆ cyclic alkene or aromatic group, provided that any coordinating moiety contains heteroatoms N, O, S;
R³ is a non-amidrazone ligand independently selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is the number of fluorinated amidrazone ligands bonded to M, x is from 1 to 5;
y is the number of the neutral ligands D bonded to M, y is from 0 to 5; and
z is the number of the non-amidrazone ligands R³ bonded to M, z is from 0 to 5.

The molecules in the above formula are formulated in the form of a monomer, or different combinations such as dimers or trimers.

The disclosed fluorinated metal-amidrazonide precursors may be [Me₂N—N═C(CF₃)O]AlEt₂, [Me₂N—N═C(CF₃)O]₂AlEt, [Me₂N—N═C(CF₃)O]₂Cu, [Me₂N—N═C(CF₂H)O]₂Cu, [Me₂N—N═C(CF₃)O]₂Ni, [Me₂N—N═C(CF₂H)O]₂Ni, [Me₂N—N═C(CF₂Me)O]₂Ni, [Me₂N—N═C(CF₃)O][CH₂C(CH₃)CH₂]Ni, and [Me₂N—N═C(CF₂Me)O][CH₂C(CH₃)CH₂]Ni.

The disclosed fluorinated metal-amidrazonide precursors is bis(N,N′-dimethyl-trifluoroacetohydrazonide)nickel(II) [Me₂N—N═C(CF₃)O]₂Ni.

Exemplary disclosed fluorinated metal-amidrazonide precursors may be Ni[Me₂N—N═C(CF₃)O]₂, Li—OC(CF₃)═N—NMe₂, and Na—OC(CF₃)═N—NMe₂.

Exemplary disclosed fluorinated metal-amidrazonide precursors also include Cu[Me₂N—N═C(CF₃)O], Ag[Me₂N—N═C(CF₃)O], Au[Me₂N—N═C(CF₃)O], Ag[Me₂N—N═C(CF₂CF₃)O], Cu[MeEtN—N═C(CF₃)O], Ag[MeEtN—N═C(CF₃)O], Au[MeEtN—N═C(CF₃)O], Ag[MeEtN—N═C(CF₂CF₃)O], tmsv·Cu[Me₂N—N═C(CF₃)O], tmsv·Ag[Me₂N—N═C(CF₃)O], tmsv·Au[Me₂N—N═C(CF₃)O], tmsv·Ag[Me₂N—N═C(CF₂CF₃)O], tmsv·Cu[MeEtN—N═C(CF₃)O], tmsv·Ag[MeEtN—N═C(CF₃)O], tmsv·Au[MeEtN—N═C(CF₃)O], tmsv·Ag[MeEtN—N═C(CF₂CF₃)O], tmsv·Cu[Me₂N—N═C(CF₃)O]₂, (Me₃Si)₂-acetylene·Cu[Me₂N—N═C(CF₃)O], (Me₃Si)₂-acetylene·Ag[Me₂N—N═C(CF₃)O], (Me₃Si)₂-acetylene·Au[Me₂N—N═C(CF₃)O], (Me₃Si)₂-acetylene·Ag[Me₂N—N═C(CF₂CF₃)O], (Me₃Si)₂-acetylene·Cu[MeEtN—N═C(CF₃)O], (Me₃Si)₂-acetylene·Ag[MeEtN—N═C(CF₃)O], (Me₃Si)₂-acetylene·Au[MeEtN—N═C(CF₃)O], (Me₃Si)₂-acetylene·Ag[MeEtN—N═C(CF₂CF₃)O], (Me₃Si)₂-acetylene·Cu[Me₂N—N═C(CF₃)O]₂, Me₃P·Cu[Me₂N—N═C(CF₃)O], Me₃P·Ag[Me₂N—N═C(CF₃)O], Me₃P·Au[Me₂N—N═C(CF₃)O], Me₃P·Ag[Me₂N—N═C(CF₂CF₃)O], Me₃P·Cu[MeEtN—N═C(CF₃)O], Me₃P·Ag[MeEtN—N═C(CF₃)O], Me₃P·Au[MeEtN—N═C(CF₃)O], Me₃P·Ag[MeEtN—N═C(CF₂CF₃)O], Me₃P·Cu[Me₂N—N═C(CF₃)O]₂, Et₃P·Cu[Me₂N—N═C(CF₃)O], Et₃P·Ag[Me₂N—N═C(CF₃)O], Et₃P·Au[Me₂N—N═C(CF₃)O], Et₃P·Ag[Me₂N—N═C(CF₂CF₃)O], Et₃P·Cu[MeEtN—N═C(CF₃)O], Et₃P·Ag[MeEtN—N═C(CF₃)O], Et₃P·Au[MeEtN—N═C(CF₃)O], Et₃P·Ag[MeEtN—N═C(CF₂CF₃)O], Et₃P·Cu[Me₂N—N═C(CF₃)O]₂, (MeO)₃P·Cu[Me₂N—N═C(CF₃)O], (MeO)₃P·Ag[Me₂N—N═C(CF₃)O], (MeO)₃P·Au[Me₂N—N═C(CF₃)O], (MeO)₃P·Ag[Me₂N—N═C(CF₂CF₃)O], (MeO)₃P·Cu[MeEtN—N═C(CF₃)O], (MeO)₃P·Ag[MeEtN—N═C(CF₃)O], (MeO)₃P·Au[MeEtN—N═C(CF₃)O], (MeO)₃P·Ag[MeEtN—N═C(CF₂CF₃)O], (MeO)₃P·Cu[Me₂N—N═C(CF₃)O]₂, Mn[Me₂N—N═C(CF₃)O]₂, Ca[Me₂N—N═C(CF₃)O]₂, Mg[Me₂N—N═C(CF₃)O]₂, Co[Me₂N—N═C(CF₃)O]₂, Sr[Me₂N—N═C(CF₃)O]₂, Zn[Me₂N—N═C(CF₃)O]₂, Cr[Me₂N—N═C(CF₃)O]₂, Ti[Me₂N—N═C(CF₃)O]₂, Cu[MeEtN—N═C(CF₃)O]₂, Mn[MeEtN—N═C(CF₃)O]₂, Ca[MeEtN—N═C(CF₃)O]₂, Mg[MeEtN—N═C(CF₃)O]₂, Co[MeEtN—N═C(CF₃)O]₂, Sr[MeEtN—N═C(CF₃)O]₂, Ni[MeEtN—N═C(CF₃)O]₂, Zn[MeEtN—N═C(CF₃)O]₂, Cr[MeEtN—N═C(CF₃)O]₂, Ti[MeEtN—N═C(CF₃)O]₂, AI[Me₂N—N═C(CF₃)O]₃, Ga[Me₂N—N═C(CF₃)O]₃, In[Me₂N—N═C(CF₃)O]₃, Ti[Me₂N—N═C(CF₃)O]₃, Sc[Me₂N—N═C(CF₃)O]₃, CpTi[Me₂N—N═C(CF₃)O]₂, CpZr[Me₂N—N═C(CF₃)O]₂, CpHf[Me₂N—N═C(CF₃)O]₂, CpV[Me₂N—N═C(CF₃)O]₂, CpSc[Me₂N—N═C(CF₃)O]₂, CpCe[Me₂N—N═C(CF₃)O]₂, CpY[Me₂N—N═C(CF₃)O]₂, CpLa[Me₂N—N═C(CF₃)O]₂, EtAI[Me₂N—N═C(CF₃)O]₂, EtGa[Me₂N—N═C(CF₃)O]₂, EtIn[Me₂N—N═C(CF₃)O]₂, MeAl[Me₂N—N═C(CF₃)O]₂, MeGa[Me₂N—N═C(CF₃)O]₂, MeIn[Me₂N—N═C(CF₃)O]₂, sBuAl[Me₂N—N═C(CF₃)O]₂, sBuGa[Me₂N—N═C(CF₃)O]₂, sBuIn[Me₂N—N═C(CF₃)O]₂, iPrAl[Me₂N—N═C(CF₃)O]₂, iPrGa[Me₂N—N═C(CF₃)O]₂, iPrIn[Me₂N—N═C(CF₃)O]₂, Cp₂Ti[Me₂N—N═C(CF₃)O]₂, Cp₂Zr[Me₂N—N═C(CF₃)O]₂, Cp₂Hf[Me₂N—N═C(CF₃)O]₂, EtCp₂Ti[Me₂N—N═C(CF₃)O]₂, EtCp₂Zr[Me₂N—N═C(CF₃)O]₂, EtCp₂Hf[Me₂N—N═C(CF₃)O]₂, MeCp₂Ti[Me₂N—N═C(CF₃)O]₂, MeCp₂Zr[Me₂N—N═C(CF₃)O]₂, MeCp₂Hf[Me₂N—N═C(CF₃)O]₂, iPrCp₂Ti[Me₂N—N═C(CF₃)O]₂, iPrCp₂Zr[Me₂N—N═C(CF₃)O]₂, iPrCp₂Hf[Me₂N—N═C(CF₃)O]₂, CpTi[Me₂N—N═C(CF₃)O]₃, CpZr[Me₂N—N═C(CF₃)O]₃, CpHf[Me₂N—N═C(CF₃)O]₃, EtCpTi[Me₂N—N═C(CF₃)O]₃, EtCpZr[Me₂N—N═C(CF₃)O]₃, EtCpHf[Me₂N—N═C(CF₃)O]₃, MeCpTi[Me₂N—N═C(CF₃)O]₃, MeCpZr[Me₂N—N═C(CF₃)O]₃, MeCpHf[Me₂N—N═C(CF₃)O]₃, iPrCpTi[Me₂N—N═C(CF₃)O]₃, iPrCpZr[Me₂N—N═C(CF₃)O]₃, and iPrCpHf[Me₂N—N═C(CF₃)O]₃, wherein “Cp” represents cyclopentadienyl.

The disclosed fluorinated metal-amidrazonide precursors may be useful for fabrication of metal, metal oxide, metal oxyfluoride, metal fluoride, or metal containing mixed-metal oxyfluoride films for various deposition and coating applications. Containing fluorine in metal-containing films may improve resistance to oxidation, chemical and thermal degradation, lower the index of refraction (RI) and improve ionic conductivity, giving them uses in a broad number of applications.

The disclosed includes methods for synthesizing the fluorinated metal-amidrazonide precursors. First, as shown in the Examples that follow, the fluorinated metal-amidrazonide precursors may be synthesized by directly reacting Me₂NNHC(═O)CₓH_{y}F_{z} with an alkyl metal (M(alkyl)n), that is, Me₂NNHC(═O)CₓH_{y}F_{z} (1-n equiv.) is dissolved in THF and added drop wise to M(alkyl)n (1 equiv.) at −78° C. under N₂ and allowed to reach room temperature. The solvent is removed under vacuum the resulting material distilled at 70° C. to 150° C. (kPa<0.01). Secondly, as shown in the Examples that follow, the fluorinated metal-amidrazonide precursors may be synthesized by reacting Me₂NNHC(═O)CₓH_{y}F_{z} with metal halide (MXₙ), that is, Me₂NNHC(═O)CₓH_{y}F_{z} (n equiv.) is dissolved in THF and reacted with excess of a base (LiNH₂, NaH, KH, etc) at 0° C. under N₂ and allowed to reach room temperature. The suspension was filtered into a suspension of MXₙ at −20° C. to 0° C. and allowed to stir overnight at room temperature. The suspension is filtered and the solvent removed under vacuum. The resulting material is distilled or sublimed at 80° C. to 150° C. (kPa<0.01).

The disclosed also includes a method or process for metal fluoride/oxyfluoride-containing deposition, which is a method to form metal, or fluorine-containing depositions such as films, continuous, partially continuous, non-continuous deposits, or dots, where the fluorinated metal-amidrazonide precursors is used in chemical deposition such as ALD, MLD (molecular layer deposition), CVD, SOD, mist coating dip coating, slit coating techniques, in combination with or without one or more reactants, typically O-sources such as O₂, O₃, H₂O, H₂O₂, NO, NO₂, N₂O, H₂ and other nitrogen-oxygen molecules, N-sources such as ammonia or a hydrazine, P-source such as PHs, TMPO (trimethyl phosphate), S-source such as H₂S, mercaptan, and combination thereof. The process may be for instance assisted by heating of substrates, using direct or remote plasma, and/or light of wavelengths from 120 to 800 nm.

It has been known, the existing fluorinated metal precursors have drawbacks, although they have been used in semiconductor applications, for example,
1). Common processes for deposition of metal-fluorine containing deposits require fluorine containing co-reactants, such as pyridine-HF (C₅H₆FN), HF, SF₆, TiF₄, etc., which are often highly toxic to the user and may be environmentally damaging by either depleting ozone in the atmosphere and/or contributing to the greenhouse effect;
2). Use of plasma processes is often necessary when using more benign fluorine sources, such as CF₄. This may lead to uniformity issues, particularly when depositing on complex 3D structures and/or on uneven/inconsistent surfaces, such as powders;
3). Current single-source metal-fluorine precursors, such as M-(HFAC)n compounds (HFAC represents hexafluoroacetylacetonate), have highly hydrophobic surfaces which may lead to poor chemisorption, therefore narrowing process windows;
4). M-(HFAC)n often have high thermal stability which may also slow chemisorption, and require elevated process temperatures which may be unsuitable for many temperature-sensitive substrates; and
5). Due to the chemical structure of HFAC ligands, chemical modification may be challenging which reduces the ability to modify physical properties as desired between different metals.

Whereas, the disclosed fluorinated metal-amidrazonide precursors has the following unique advantages.
1). Inclusion of fluorine in the backbone of these fluorinated metal-amidrazonide compounds allows for ‘single-source’ deposition of metal-fluorine containing deposits without the need for fluorine containing co-reactants, such as pyridine·HF (C₅H₆FN), SF₆, TiF₄, etc. which are often hazardous to the user and/or environment;
2). Inclusion of fluorine in these fluorinated metal-amidrazonide precursors provides a method by which fluorine-containing deposits may be formed with simple co-reactants such as H₂O, H₂, O₃, O₂, without the need for plasma-enhanced processes. This may improve conformality which is particularly important when depositing on complex, 3D structures;
3). Use of amidrazone-type ligands as the primary backbone in the disclosed fluorinated metal-amidrazonide precursors increases the polarity of them compared to their HFAC equivalents. This may enable more rapid chemisorption at a wider range of temperatures;
4). As the disclosed fluorinated metal-amidraonide precursors contain N—N bonds, they may be more thermally unstable and vulnerable to milder co-reactants allowing for improved processing time. As these precursors are tighter, 5-membered rings, they also allow for preparation of stable heteroleptic precursors that may include more reactive R-groups, such as amides, hydrides, cyclopentadienyls and alkyl chains, which may otherwise disproportionate in combination with HFAC; and
5). As these fluorinated ligands are prepared by combination of hydrazines and fluorinated esters, they may be easily chemically modified to alter physical properties from readily commercially available materials. This may include, but is not limited to, lengthening the fluorinated backbone, or modifying the —R¹R²N groups to be longer, more sterically hindering, or inclusion of chelating moieties.

The resulting metal-containing films deposited by the disclosed fluorinated metal-amidrazonide precursors are metal oxide, such as NiO, metal oxyfluoride, metal fluoride, or metal-containing mixed-metal oxyfluoride films.

Purity of the disclosed metal-containing film-forming compositions including the disclosed fluorinated metal-amidrazonide precursors is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by ¹H NMR and gas liquid chromatography with mass spectrometry. The disclosed metal-containing film-forming composition may contain any of the following impurities: pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed metal-containing film-forming composition may also result in metal impurities at the 0 ppbw to 1 ppmw, preferably 0-500 ppbw (part per billion weight) level. These metal impurities may include, but are not limited to, Aluminum (AI), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

The disclosed fluorinated metal-amidrazonide precursors are provided in a high purity vessel, typically made of stainless steel, carbon steel, or of aluminum, which has previously been dried down to <100 ppb H₂O residual and which optionally may be passivated to limit decomposition of the precursor therein over time. The passivation process generally involves the exposure of the high purity vessel to a silylating agent, which in this case may be the target precursor itself, or a silane or a polysilane.

The vapor of the disclosed fluorinated metal-amidrazonide precursors may be delivered neat in the absence of a carrier gas into a process chamber when the vapor pressure of the precursor at a vessel temperature ranging from 0° C. to approximately 150° C. is typically >50 torr, preferably >300 torr.

Also disclosed are methods for forming metal-containing layers on a substrate using a vapor deposition process. The disclosed metal-containing film-forming compositions are suitable for chemical vapor deposition (CVD). More particularly, the disclosed metal-containing film-forming compositions are capable of surface saturation, self-limited growth per cycle, and perfect step coverage on aspect ratios ranging from approximately 2:1 to approximately 200:1, and preferably from approximately 20:1 to approximately 100:1. Additionally, the disclosed metal-containing film-forming compositions have high decomposition temperatures, indicating good thermal stability to enable CVD. The high decomposition temperatures permit CVD at higher temperatures, resulting in films having higher purity.

The disclosed method may be useful in the manufacture of semiconductor, photovoltaic, LCD-TFT, flat panel type devices. The disclosed metal-containing film-forming compositions may be used to deposit metal-containing films using any deposition methods known to those of skill in the art. Examples of suitable deposition methods include CVD. Exemplary CVD methods include thermal CVD, plasma enhanced CVD (PECVD), pulsed CVD (PCVD), low pressure CVD (LPCVD), sub-atmospheric CVD (SACVD) atmospheric pressure CVD (APCVD), hot-wire CVD (HWCVD, also known as cat-CVD, in which a hot wire serves as an energy source for the deposition process), radicals incorporated CVD, ALD, thermal ALD, plasma enhanced ALD (PEALD), spatial ALD, hot-wire ALD (HWALD), radicals incorporated ALD, and combinations thereof, Super critical fluid deposition may also be used. The deposition method is preferably ALD, PE-ALD, spatial ALD in order to provide suitable step coverage and film thickness control.

The disclosed metal-containing film-forming compositions may be supplied either in neat form or in a blend with a suitable solvent, such as ethyl benzene, xylene, mesitylene, decalin, decane, dodecane. The disclosed fluorinated metal-amidrazonide precursors may be present in varying concentrations in the solvent.

The neat or blended disclosed metal-containing film-forming compositions are introduced into a reactor in vapor form by conventional means, such as tubing and/or flow meters. The vapor form may be produced by vaporizing the neat or blended composition through a conventional vaporization step such as direct vaporization, distillation, by bubbling, or by using a sublimator. The neat or blended composition may be fed in liquid state to a vaporizer where it is vaporized before it is introduced into the reactor. Alternatively, the neat or blended composition may be vaporized by passing a carrier gas into a container containing the composition by bubbling the carrier gas into the composition. The carrier gas may include, but is not limited to, Ar, He, N₂, and mixtures thereof. Bubbling with a carrier gas may also remove any dissolved oxygen present in the neat or blended composition. The carrier gas and composition are then introduced into the reactor as a vapor,

For the disclosed fluorinated metal-amidrazonide precursors that have low vapor pressures, the vapors of the disclosed fluorinated metal-amidrazonide precursors are fed to the process chamber with a carrier gas in either a bubbler, a vapor draw or a direct liquid injection system. The carrier gas may include, but is not limited to, Ar, He, N₂, H₂ or a combination thereof. Bubbling with a carrier gas may also remove any dissolved oxygen present in the precursors. The carrier gas and the precursor are then introduced into a processing chamber or a reactor as a vapor. The process chamber is usually held at a pressure below atmospheric pressure, preferably ranging from 0.01 to 500 torr, and more preferably ranging from 1 to 100 torr.

If necessary, the container containing the disclosed metal-containing film-forming compositions may be heated to a temperature that permits the composition to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

The reactor or processing chamber may be any enclosure chamber within a device in which deposition methods take place such as without limitation, a parallel-plate type reactor, a cold-wall type reactor, a hot-wall type reactor, a single-wafer reactor, a multi-wafer reactor, a powder ALD reactor, other types of deposition systems under conditions suitable to cause the compounds to react and form the deposition films. One of ordinary skill in the art will recognize that any of these reactors may be used for either ALD or CVD deposition processes.

The reactor contains one more substrates onto which the films will be deposited. A substrate is generally defined as a material on which a process is conducted. The substrates may be any suitable substrate used in semiconductor, photovoltaic, fiat panel, LCD-TFT device manufacturing. Examples of suitable substrates include wafers, such as silicon, silica, glass, GaAs wafers. The wafer may have one more layers of differing materials deposited on it from a previous manufacturing step. For example, the wafers may include a dielectric layer. Furthermore, the wafers may include silicon layers such as crystalline, amorphous, porous, etc., silicon oxide layers, silicon nitride layers, silicon oxy nitride layers, carbon doped silicon oxide (SiCOH) layers, metal, metal oxide, metal nitride layers such as Ti, Ru, Ta, etc. and combinations thereof. Additionally, the wafers may include copper layers noble metal layers, e.g., platinum, palladium, rhodium, and gold. The layers may be planar or patterned. The disclosed processes may deposit the metal chloride layer directly on the wafer or directly on one or more layers on top of the wafer (when patterned layers form the substrate). Furthermore, one of ordinary skill in the art will recognize that the terms “film” and “layer” used herein refer to a thickness of some material laid on spread over a surface and that the surface may be a hole, a trench or a line. Throughout the specification and claims, the wafer and any associated layers thereon are referred to as substrates. The patterned layers may be alternating layers of two specific layers such as SiO and SiN used in 3D NAND.

The substrate final application is not limited to the present invention, but this technology may find particular benefits for the following types of substrates: silicon wafers, glass wafers and panels, beads, powders and nano-powders, monolithic porous media, printed circuit board, plastic sheets, etc. Exemplary powder substrates include a powder used in rechargeable battery technology. A non-limiting number of powder materials include NMC (Lithium Nickel Manganese Cobalt Oxide), LCO (Lithium Cobalt Oxide), LFP (Lithium Iron Phosphate), and other battery cathode materials.

The temperature and the pressure within the processing chamber or reactor are held at conditions suitable for vapor depositions, such as CVD. In other words, after introduction of the vaporized disclosed metal-containing film-forming composition into the chamber, conditions within the chamber are such that at least part of the precursor is deposited onto the substrate to form a layer. For instance, the pressure in the reactor or the deposition pressure may be held between about 10-3 torr and about 500 torr, preferably between about 10⁻² torr and 500 torr, more preferably between about 1 torr and 100 torr, as required per the deposition parameters. Likewise, the temperature in the reactor may be held between between 50° C. and 800° C., preferably between approximately 50° C. and approximately 600° C. One of ordinary skill in the art will recognize that “at least part of the precursor is deposited” means that some all of the precursor reacts with adheres to the substrate.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 600° C. When a plasma deposition process is utilized, the deposition temperature may range from approximately 50° C. to approximately 500° C., preferably, from approximately 100° C. to approximately 500° C., more preferably, from approximately 150° C. to approximately 500° C. Alternatively, when a thermal process is performed, the deposition temperature may range from approximately 100° C. to approximately 600° C.

In addition to the disclosed fluorinated metal-amidrazonide precursors, other precursor or co-reactants may be introduced into the reactor. When a target deposited film is a conductive film, the co-reactant may be H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof. Preferably, the co-reactant is H₂ or NH₃. Alternatively, when a target deposited film is a dielectric film, the co-reactant may be an oxidizing gas such as one of O₂, O₃, H₂O, H₂O₂, NO, N₂O, NO₂, oxygen containing radicals such as O— or OH—, alcohol, silanols, aminoalcohols, carboxylic acids, para-formaldehyde, carboxylic acids, formic acid, acetic acid, propionic acid, and mixtures thereof. Preferably, the oxidizing gas is selected from the group consisting of O₃, H₂O₂ and H₂O.

In addition, the co-reactant is at least one secondary precursor selected from silanes and polysilanes, alkylsilanes, halosilanes such as monochlorosilane (MCS, SiH₃Cl), dichlorosilane (DCS, SiH₂Cl₂), trichlorosilane (TCS, SiHCl₃), and silicon tetrachloride (STC, SiCl₄), polyhalopolysilanes, germane, chlorogermane, digermane, polygermanes, halogermanes, phosphines, boranes or halide containing gases.

Furthermore, the co-reactants may be treated by a plasma, in order to decompose the precursor or reactant into its radical form, at least one of H₂, N₂ and O₂ or an inert gas (He, Ar, Kr, Xe) may be utilized depending on the target film composition, when treated with plasma. The plasma source may be a N₂ plasma, N₂/He plasma, N₂/Ar plasma, NH₃ plasma, NH₃/He plasma, NH₂/AR plasma, He plasma, Ar plasma, H₂ plasma, H₂/He plasma, H₂/organic amine plasma, and mixtures thereof. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactants may be introduced into a direct plasma reactor, which generates plasma in the reaction chamber, to produce the plasma-treated reactant in the processing chamber. Exemplary direct plasma reactors include the Titan™ PECVD System produced by Trion Technologies. The co-reactants may be introduced and held in the processing chamber prior to plasma processing. Alternatively, the plasma processing may occur simultaneously with the introduction of the precursor or reactant. In-situ plasma is typically a≥13.56 MHz RF inductively coupled plasma that is generated between the showerhead and the substrate holder. The substrate and the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactants using in-situ plasma is typically less than achieved using a remote plasma source for the same power input and is therefore not as efficient in reactant dissociation as a remote plasma system, which may be beneficial for the deposition of films on substrates easily damaged by plasma.

Alternatively, the plasma-treated co-reactants may be produced outside of the processing chamber, for example, a remote plasma to treat the co-reactants prior to passage into the processing chamber.

The vapor deposition process may be selective to certain surfaces or non-selective.

The vapor deposition process may be thermally driven, or enhanced by plasma activation, light activation, microwave activation, or other suitable means to activate the molecule and the growth process.

Furthermore, a dilution gas may be added to the process, and is selected from Ar, He, N₂, H₂ or combinations thereof.

The disclosed fluorinated metal-amidrazonide precursors and co-reactants may be introduced into the reactor either simultaneously (CVD), sequentially (ALD) or different combinations thereof. The reactor may be purged with an inert gas (for example, N₂, Ar, Kr, Xe) between the introduction of the fluorinated metal-amidrazonide precursors and the introduction of the co-reactant. Alternatively, the co-reactant and the fluorinated metal-amidrazonide precursors may be mixed together to form a co-reactant/compound mixture, and then introduced to the reactor in a mixture form (CVD, thermal CVD or Epitaxy). Another example is to introduce the co-reactant continuously and to introduce the disclosed fluorinated metal-amidrazonide precursors by pulse (pulsed CVD).

The CVD conditions within the chamber allow the disclosed metal-containing film-forming composition adsorbed or chemisorbed on the substrate surface to react and form a metal fluoride film on the substrate. In some embodiments, it is believed that plasma-treating the co-reactant may provide the co-reactant with the energy needed to react with the disclosed metal fluoride film-forming composition.

Depending on what type of film is desired to be deposited, an additional precursor compound may be introduced into the reactor. The additional precursor may be used to provide additional elements to the metal fluoride film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminum), additional different metal elements, and mixtures thereof. When an additional precursor compound is utilized, the resultant film deposited on the substrate contains the metal fluoride in combination with an additional element.

Depending on the co-reactants, the deposition process may contain other elements than those present in the disclosed precursors, such as Ge, Ga, C, B, Sn, Al, N, O, S, Se, Te, In, Zn, Cd, Hg.

In ALD processes, ALD conditions within the chamber allow the disclosed metal-containing film-forming compositions adsorbed or chemisorbed on the substrate surface to react and form a film on the substrate. In some embodiments, Applicants believe that plasma-treating co-reactant may provide the co-reactant with the energy needed to react with the disclosed metal-containing film-forming compositions (PEALD). The co-reactant may be treated with plasma prior subsequent to introduction into the chamber.

The disclosed metal-containing film-forming compositions and co-reactants may be introduced into the reactor sequentially (i.e., ALD). The reactor may be purged with an inert gas (e.g., N₂, He, Ar, Kr, or Xe) between the introduction of each of the disclosed metal fluoride film-forming compositions, any additional precursors, and the co-reactants. Another example is to introduce the co-reactant continuously and to introduce the metal fluoride film-forming composition by pulse, while activating the co-reactant sequentially with a plasma, provided that the metal fluoride film-forming composition and the non-activated co-reactant do not substantially react at the chamber temperature and pressure conditions (CW PEALD).

The disclosed metal-containing film-forming compositions and co-reactants may be introduced into the reactor simultaneously (i.e., CVD). Another example is to introduce the co-reactant continuously and to introduce the metal fluoride film-forming composition by pulse, while activating the co-reactant simultaneously with a plasma, provided that the metal fluoride film-forming composition and the non-activated co-reactant do not substantially react at the chamber temperature and pressure conditions (CW PECVD).

Each pulse of the disclosed metal-containing film-forming compositions may last for a time period ranging from about 0.01 seconds to about 120 seconds, alternatively from about 1 seconds to about 80 seconds, alternatively from about 5 seconds to about 30 seconds. The co-reactant may also be pulsed into the reactor, In such embodiments, the pulse of each may last for a time period ranging from about 0.01 seconds to about 120 seconds, alternatively from about 1 seconds to about 30 seconds, alternatively from about 2 seconds to about 20 seconds. In another alternative, the vaporized disclosed metal-containing film-forming compositions and co-reactants may be simultaneously sprayed from different sectors of a shower head without mixing of the composition and the reactant under which a susceptor holding several wafers is spun (spatial ALD).

Depending on particular process parameters, deposition may take place for a varying length of time. Generally, deposition may be allowed to continue as long as desired necessary to produce a film with the necessary properties. Typical film thicknesses may vary from several angstroms to several hundreds of microns, and typically from a molecular monolayer to several hundreds of microns, preferably from 1 to 500 nm, more preferably from 2 nm and 100 nm, depending on the specific deposition process.

The deposition process may also be performed as many times as necessary to obtain a desired film.

In one non-limiting exemplary CVD process, the vapor phase of the disclosed metal-containing film-forming compositions is introduced into the reactor, where it is contacted with a suitable substrate. The composition may include a fluorinated metal-amidrazonide precursor and a co-reactant. Excess composition may then be removed from the reactor by purging and/or evacuating the reactor. The fluorinated metal-amidrazonide precursor may absorb on the substrate and the co-reactant reacts with the absorbed metal fluoride film-forming composition in a self-limiting manner. If the desired film is a metal oxide, this one step process may provide the desired film thickness and may be repeated until a film having the necessary thickness has been obtained.

When the co-reactant in this exemplary CVD process is treated with a plasma, the exemplary CVD process becomes an exemplary PECVD process. The co-reactant may be treated with plasma prior subsequent to introduction into the chamber.

The disclosed metal-containing film-forming compositions may be used for liquid phase film deposition of metal-containing films, including but not limited to spin coating, dip coating or spray coating. In this case, a formulation containing the disclosed precursor is coated on a substrate, which is subsequently annealed to yield a thin film.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, the NiO film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the resulting film. This in turn tends to improve the resistivity of the metal-containing film.

After annealing, the metal-containing films deposited by any of the disclosed processes may have a bulk resistivity at room temperature of approximately 50 μohmcm to approximately 1,000 μohmcm. Room temperature is approximately 20° C. to approximately 28° C. depending on the season. Bulk resistivity is also known as volume resistivity. One of ordinary skill in the art will recognize that the bulk resistivity is measured at room temperature on the metal-containing films that are typically approximately 50 nm thick. The bulk resistivity typically increases for thinner films due to changes in the electron transport mechanism. The bulk resistivity also increases at higher temperatures.

### EXAMPLES

The following non-limiting examples are provided to further illustrate embodiments of the invention. However, the examples are not intended to be all inclusive and are not intended to limit the scope of the inventions described herein.

### Example 1: Synthesis of [Me₂N—N═C(CF₃)O]AlEt₂ (1)

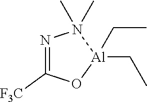

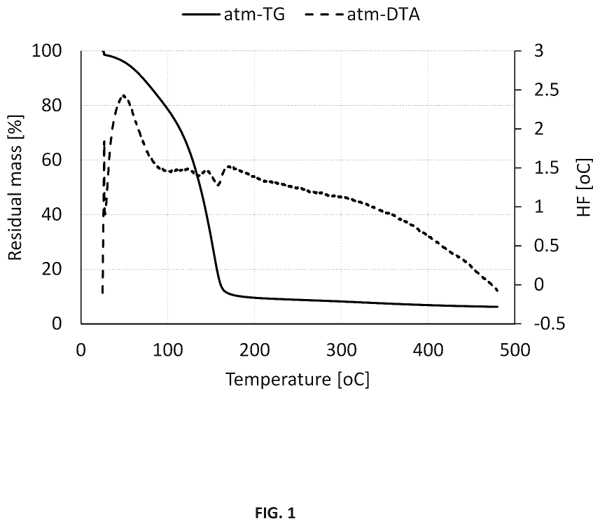

One equivalent of Me₂N—NHC(═O)CF₃ was dissolved in THF and added drop wise to one equivalent of triethyl aluminum at −78° C. under N₂ and allowed to reach room temperature. The solvent was removed i.v. and the resulting yellow liquid was distilled at 70° C. (kPa<0.01) 1H NMR (C6D6, 400 MHz): 1.92 (6H, br s), 1.11 (6H, t, 3J=8.2 Hz), −0.02 (4H, q, 3J=8.2 Hz). TG measurement was carried out under the following measurement conditions: rate of temperature increase set to 10.0° C./min, open cup under N₂ flow at 1 atm. Sample weight of 29.0 mg was evaporated at 18° C. with ~20% residue remaining. 50% evaporation using open cup TGA method under N₂ at 1 atm; T=157° C. FIG. 1 is a graph of the thermogravimetric analysis (TGA) at 760 Torr of [Me₂N—N═C(CF₃)O]AlEt₂ illustrating the weight loss vs. temperature in conditions representative of delivery conditions (10° C./min).

### Example 2: Synthesis of [Me₂N—N═C(CF₃)O]₂AlEt (2)

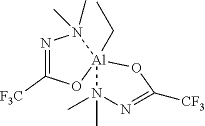

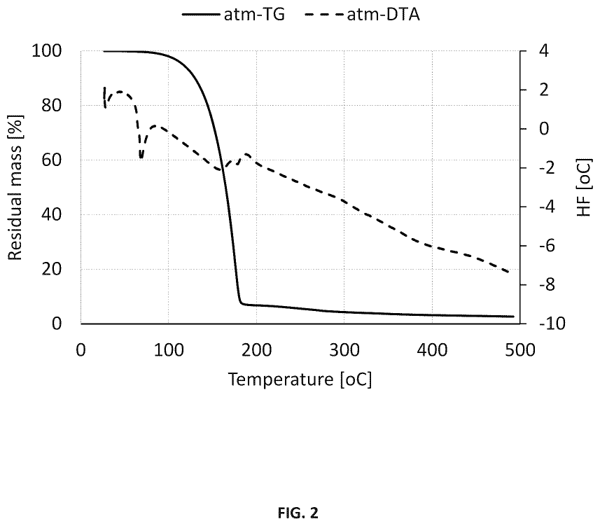

Two equivalents of Me₂N—NHC(═O)CF₃ was dissolved in THF and added drop wise to one equivalent of triethyl aluminum at −78° C. under N₂ and allowed to reach room temperature. The solvent was removed i.v. and the resulting white solid was sublimed at 55° C. (kPa<0.01; M.P. 67C) 1H NMR (C₆D₆, 400 MHz): 2.12 (6H, br s), 2.26 (6H, br s), 1.12 (3H, t, 3J=6.3 Hz), −0.01 (2H, q, 3J=6.3 Hz). TG measurement was carried out under the following measurement conditions: rate of temperature increase set to 10.0° C./min, open cup under N₂ flow at 1 atm. Sample weight of 21.1 mg was evaporated at 182° C. with ~5.4% residue remaining. 50% evaporation using open cup TGA method under N₂ at 1 atm; T=164° C. FIG. 2 is a graph of the TGA at 760 Torr of [Me₂N—N═C(CF₃)O]₂AlEt illustrating the weight loss vs. temperature in conditions representative of delivery conditions (10° C./min).

### Example 3: Synthesis of [Me₂N—N═C(CF₃)O]₂Cu (3)

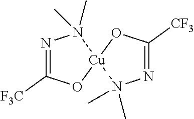

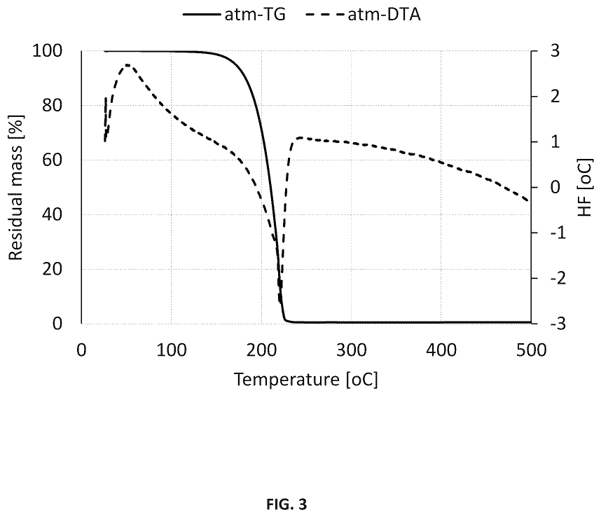

Two equivalents of Me₂N—NHC(═O)CF₃ was dissolved in THF and reacted with excess LiNH₂ at 0° C. under N₂ and allowed to reach room temperature. The suspension was filtered into a suspension of CuCl₂ at −20° C. and allowed to stir overnight, producing a deep blue solution. The suspension was filtered and the solvent removed i.v. The resulting red solid was sublimed at 85° C. (kPa<0.01). TG measurement was carried out under the following measurement conditions: rate of temperature increase set to 10.0° C./min, open cup under N₂ flow at 1 atm. Sample weight of 27.9 mg was evaporated at 230° C. with ~0.5% residue remaining. 50% evaporation using open cup TGA method under N₂ at 1 atm; T=211° C. FIG. 3 is a graph of the TGA at 760 Torr of [Me₂N—N═C(CF₃)O]₂Cu illustrating the weight loss vs. temperature in conditions representative of delivery conditions (10° C./min).

### Example 4: Synthesis of [Me₂N—N═C(CF₂H)O]₂Cu (4)

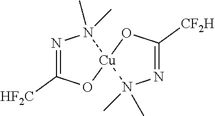

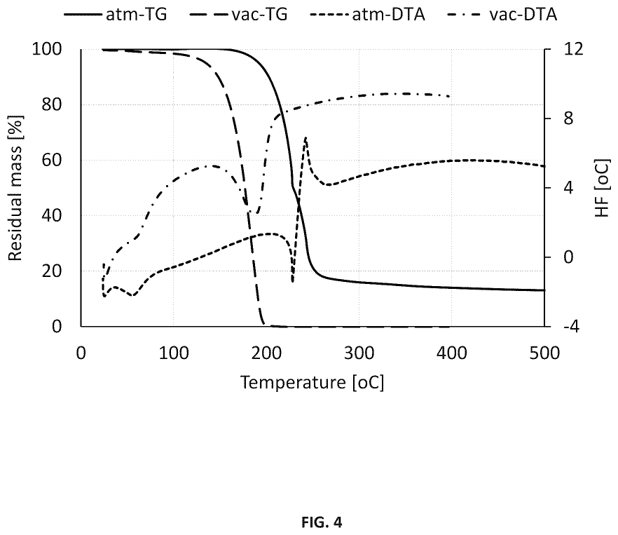

Two equivalents of Me₂N—NHC(═O)CF₂H was dissolved in THF and reacted with excess NaH at 0° C. under N₂ and allowed to reach room temperature. The suspension was filtered into a suspension of CuCl₂ at −20° C. and allowed to stir overnight, producing a deep blue solution. The suspension was filtered and the solvent removed i.v. The resulting red solid was sublimed at 100° C. (kPa<0.01). TG measurement was carried out under the following measurement conditions: rate of temperature increase set to 10.0° C./min; 1) open cup under N₂ flow at 1 atm. Sample weight of 27.5 mg was evaporated at 260° C., decomposing at 240° C. with ~13% residue remaining. 50% evaporation using open cup TGA method under N₂ at 1 atm; T=229° C.; 2) open cup at 15 Torr (vac). Sample weight of 34.0 mg was evaporated at 200° C. with <1% residue remaining. FIG. 4 is a graph of the TGA at 760 Torr (atm) and 15 torr (vac)]of [Me₂N—N═C(CF₂H)O]₂Cu illustrating the weight loss vs. temperature in conditions representative of delivery conditions (10° C./min).

### Example 5: Synthesis of [Me₂N—N═C(CF₃)O]₂Ni (5)

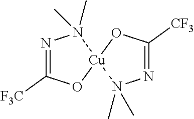

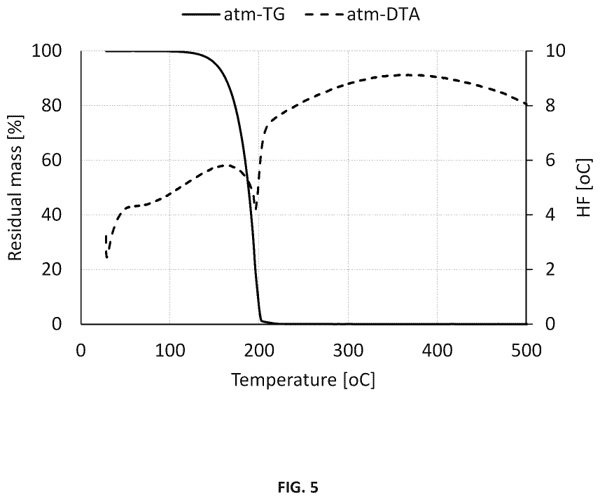

Two equivalents of Me₂N—NHC(═O)CF₃ were dissolved in THF and reacted with two equivalents of KH (added portionwise) at 0° C. under N₂ and allowed to reach room temperature (hydrogen evolution is observed during the KH addition). Then one equivalent of NiCl₂(dme) is added portionwise at 0° C. and allowed to stir overnight at room temperature, producing a light yellow solution. The suspension was filtered and the solvent removed i.v. The resulting orange solid was sublimed at 70° C. (kPa<0.01) TG measurement was carried out under the following measurement conditions: rate of temperature increase set to 10.0° C./min, open cup under N₂ at 1 atm; T=188° C. FIG. 5 is a graph of the TGA at 760 Torr of [Me₂N—N═C(CF₃)O]₂Ni illustrating the weight loss vs. temperature in conditions representative of delivery conditions (10° C./min).

### Example 6: Synthesis of [Me₂N—N═C(CF₂H)O]₂Ni (6)

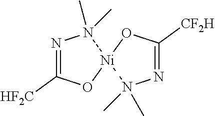

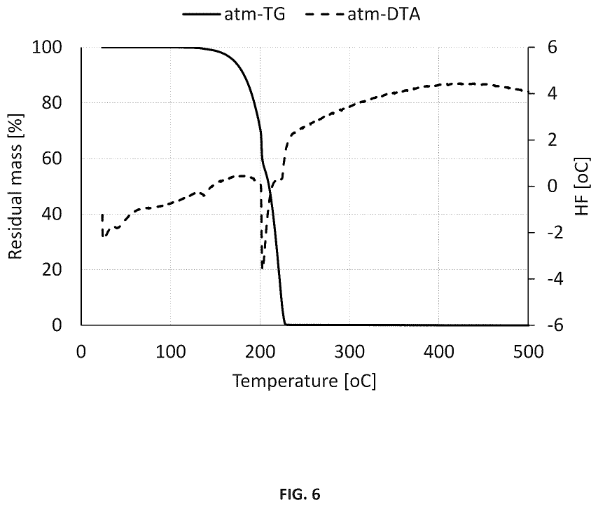

Two equivalents of Me₂N—NHC(═O)CF₂H were dissolved in THF and reacted with two equivalents of NaH (added portionwise) at 0° C. under N₂ and allowed to reach room temperature (hydrogen evolution is observed during the NaH addition). Then one equivalent of NiCl₂(dme) is added portionwise at 0° C. and allowed to stir overnight at room temperature, producing a light yellow solution. The suspension was filtered and the solvent removed i.v. The resulting orange solid was sublimed at 100° C. (kPa<0.01) TG measurement was carried out under the following measurement conditions: rate of temperature increase set to 10.0° C./min, open cup under N₂ flow at 1 atm. Sample weight of 23.1 mg was evaporated at 220° C. with <1% residue remaining. 50% evaporation using open cup TGA method under N₂ at 1 atm; T=217° C. FIG. 6 is a graph of the TGA at 760 Torr of [Me₂N—N═C(CF₂H)O]₂Ni illustrating the weight loss vs. temperature in conditions representative of delivery conditions (10° C./min).

### Example 7: Synthesis of [Me₂N—N═C(CF₂Me)O]₂Ni (7)

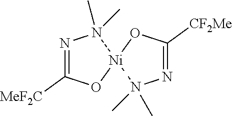

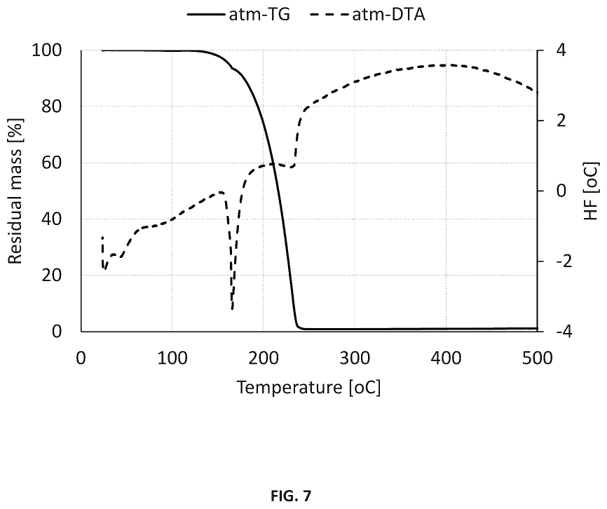

Two equivalents of Me₂N—NHC(═O)CF₂Me were dissolved in THF and reacted with two equivalents of NaH (added portionwise) at 0° C. under N₂ and allowed to reach room temperature (hydrogen evolution is observed during the NaH addition). Then one equivalent of NiCl₂(dme) is added portionwise at 0° C. and allowed to stir overnight at room temperature, producing a light yellow solution. The suspension was filtered and the solvent removed i.v. The resulting orange solid was sublimed at 100° C. (kPa<0.01) TG measurement was carried out under the following measurement conditions: rate of temperature increase set to 10.0° C./min, open cup under N₂ flow at 1 atm. Sample weight of 25.9 mg was evaporated at 245° C. with <1% residue remaining. 50% evaporation using open cup TGA method under N₂ at 1 atm; T=216° C. FIG. 7 is a graph of the TGA at 760 Torr of [Me₂N—N═C(CF₂Me)O]₂Ni illustrating the weight loss vs. temperature in conditions representative of delivery conditions (10° C./min).

### Example 8: Synthesis of [Me₂N—N═C(CF₃)O][CH₂C(CH₃)CH₂]Ni (8)

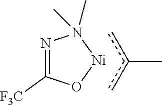

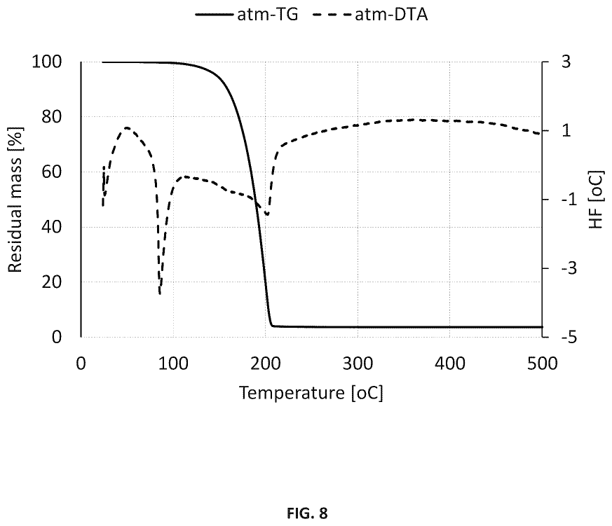

Two equivalents of Me₂N—NHC(═O)CF₃ were dissolved in THF and reacted with two equivalents of NaH (added portionwise) at 0° C. under N₂ and allowed to reach room temperature (hydrogen evolution is observed during the NaH addition). Then the previous solution is added dropwise over another solution of one equivalent of [(CH₂C(CH₃)CH₂)NiCl]₂ dissolved in THF and previously cooled at −30° C. After that the mixture is allowed to stir at room temperature for 2 h, producing a light green solution. The suspension was filtered and the solvent removed i.v. The resulting yellow solid was sublimed at 50° C. (kPa<0.01) TG measurement was carried out under the following measurement conditions: rate of temperature increase set to 10.0° C./min, open cup under N₂ flow at 1 atm. Sample weight of 25.4 mg was evaporated at 210° C. with <4% residue remaining. 50% evaporation using open cup TGA method under N₂ at 1 atm; T=190° C. FIG. 8 is a graph of the TGA at 760 Torr of [Me₂N—N═C(CF₃)O][CH₂C(CH₃)CH₂]Ni illustrating the weight loss vs. temperature in conditions representative of delivery conditions (10° C./min).

### Example 9: Synthesis of [Me₂N—N═C(CF₂Me)O][CH₂C(CH₃)CH₂]Ni (9)

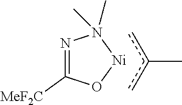

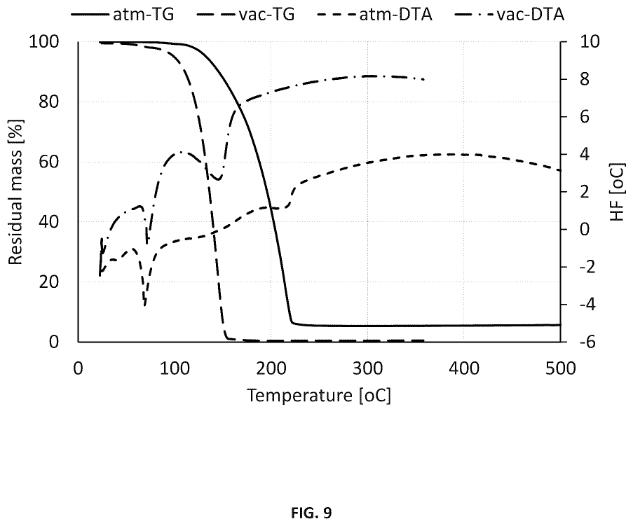

Two equivalents of Me₂N—NHC(═O)CF₂Me were dissolved in THF and reacted with two equivalents of NaH (added portionwise) at 0° C. under N₂ and allowed to reach room temperature (hydrogen evolution is observed during the NaH addition). Then the previous solution is added dropwise over another solution of one equivalent of [(CH₂C(CH₃)CH₂)NiCl]₂ dissolved in THF and previously cooled at −30° C. After that the mixture is allowed to stir at room temperature for 2 h, producing a light green solution. The suspension was filtered and the solvent removed i.v. The resulting yellow solid was recrystallized in pentane. TG measurement was carried out under the following measurement conditions: rate of temperature increase set to 10.0° C./min; 1) open cup under N₂ flow at 1 atm. Sample weight of 20.2 mg was evaporated at 230° C. with <6% residue remaining. 50% evaporation using open cup TGA method under N₂ at 1 atm; T=197° C.; 2) open cup at 15 Torr (vac). Sample weight of 22.4 mg was evaporated at 160° C. with <1% residue remaining. FIG. 9 is a graph of the TGA at 760 Torr (atm) and 15 torr (vac)] of [Me₂N—N═C(CF₂Me)O][CH₂C(CH₃)CH₂]Ni illustrating the weight loss vs. temperature in conditions representative of delivery conditions (10° C./min).

### Example 10: Gas phase metal-fluoride deposition Fluorine-doped Nickel Oxide Film Deposition

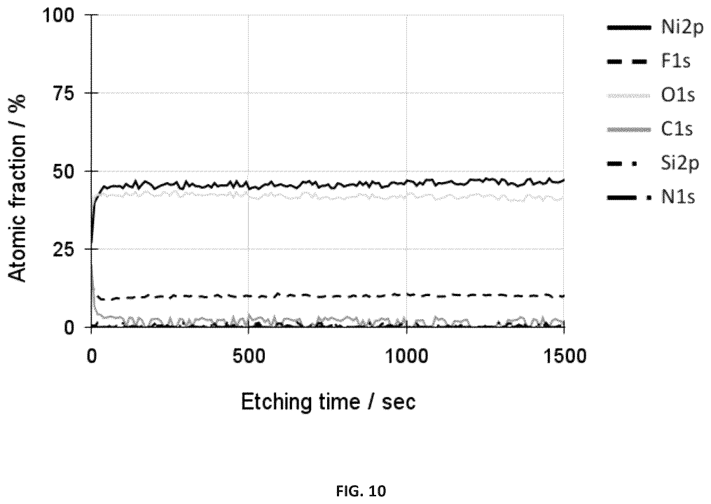

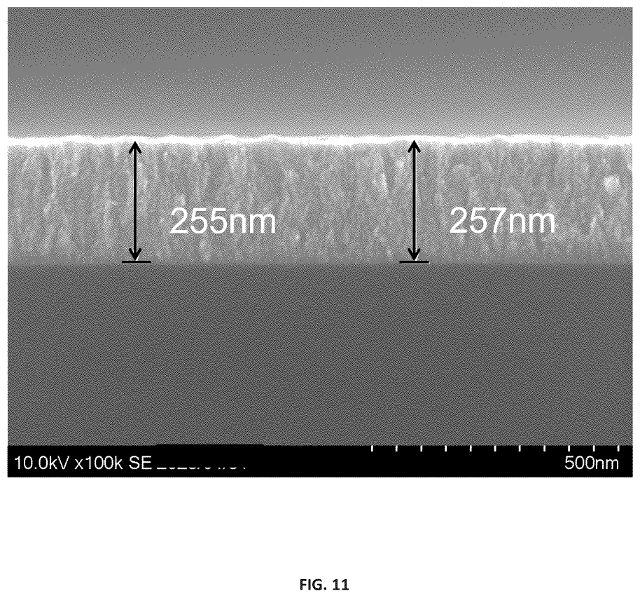

A home-made tubular reactor was used for thin film deposition experiments. The reactor was operated under a flow of nitrogen at a pressure of 1-2 mbar. The deposition of fluorine-doped nickel oxide films by CVD conditions were performed by using bis(N,N′-dimethyl-trifluoroacetohydrazonide)nickel(II) [Me₂N—N═C(CF₃)O]₂Ni (5) as a nickel-fluoride precursor and using ozone (O₃) as a co-reactant. The temperature of the reactor was kept 300° C. and the canister holding the nickel-fluoride precursor was heated at 100° C. The nickel-fluoride precursor and ozone were simultaneously delivered into the reactor for 1 hour. The deposited fluorine-doped nickel oxide films were deposited on Si(100) with HF treatment. FIG. 10 is XPS analysis of the fluorine-doped nickel oxide film over Si wafer formed using [Me₂N—N═C(CF₃)O]₂Ni. FIG. 11 is SEM analysis of the fluorine-doped nickel oxide film over Si wafer formed using [Me₂N—N═C(CF₃)O]₂Ni.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

1. A method for forming a metal-containing film on a substrate, the method comprising:
exposing the substrate to a vapor of a metal-containing film-forming composition that contains a fluorinated metal-amidrazonide precursor; and
depositing at least part of the fluorinated metal-amidrazonide precursors onto the substrate to form the metal-containing film on the substrate through a vapor deposition method,
wherein the fluorinated metal-amidrazonide precursor having the general formula 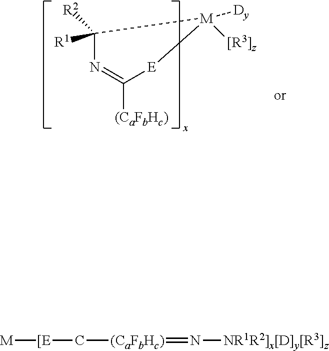
wherein
M is a transition metal or a rare earth element;
E is selected from O, S, Se or Te;
D is a monodentate, bidentate, tridentate, or a polydentate donor with a neutral charge;
CₐF_{b}H_{c} is a fluorinated backbone, wherein a≥1, b≥1, c≥0;
R¹ and R² each are independently selected from an H, a C₁-C₆ linear or branched alkyl group, a C₃-C₆ cyclic alkyl group, a C₂-C₆ linear or branched alkene group, a C₃-C₆ cyclic alkene or aromatic group, wherein any coordinating moieties contain heteroatoms N, O, S;
R³ is selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is from 1 to 5;
y is from 0 to 5; and
z is from 0 to 5.

2. The method of claim 1, wherein the transition metal is selected from Li, Na, K, Mg, Ca, Sr, Ba, Al, Ga, In, Cu, Mn, Fe, Ni, Co, Ti, Zr, Hf, V, Nb, Ta.

3. The method of claim 1, wherein the monodentate, bidentate, tridentate, or a polydentate donor contains heteroatoms N, O, P, or S, or combination thereof.

4. The method of claim 1, wherein the monodentate, bidentate, tridentate, or a polydentate donor contains alkenes, alkynes, or carbenes.

5. The method of claim 1, wherein the fluorinated metal-amidrazonide precursor is bis(N,N′-dimethyl-trifluoroacetohydrazonide)nickel(II), [Me₂NN═C(CF₃)O]₂Ni.

6. The method of claim 1, wherein the fluorinated metal-amidrazonide precursor is selected from [Me₂N—N═C(CF₃)O]AlEt₂, [Me₂N—N═C(CF₃)O]₂AlEt, [Me₂N—N═C(CF₃)O]₂Cu, [Me₂N—N═C(CF₂H)O]₂Cu, [Me₂N—N═C(CF₃)O]₂Ni, [Me₂N—N═C(CF₂Me)O]₂Ni, [Me₂N—N═C(CF₂Me)O]₂Ni, [Me₂N—N═C(CF₃)O][CH₂C(CH₃)CH₂]Ni, [Me₂N—N═C(CF₂Me)O][CH₂C(CH₃)CH₂]Ni, Ni[Me₂N—N═C(CF₃)O]₂, Li—OC(CF₃)═N—NMe₂, and Na—OC(CF₃)═N—NMe₂.

7. The method of claim 1, wherein the fluorinated metal-amidrazonide precursor is selected from Cu[Me₂N—N═C(CF₃)O], Ag[Me₂N—N═C(CF₃)O], Au[Me₂N—N═C(CF₃)O], Ag[Me₂N—N═C(CF₂CF₃)O], Cu[MeEtN—N═C(CF₃)O], Ag[MeEtN—N═C(CF₃)O], Au[MeEtN—N═C(CF₃)O], Ag[MeEtN—N═C(CF₂CF₃)O], tmsv·Cu[Me₂N—N═C(CF₃)O], tmsv·Ag[Me₂N—N═C(CF₃)O], tmsv·Au[Me₂N—N═C(CF₃)O], tmsv·Ag[Me₂N—N═C(CF₂CF₃)O], tmsv·Cu[MeEtN—N═C(CF₃)O], tmsv·Ag[MeEtN—N═C(CF₃)O], tmsv·Au[MeEtN—N═C(CF₃)O], tmsv·Ag[MeEtN—N═C(CF₂CF₃)O], tmsv·Cu[Me₂N—N═C(CF₃)O]₂, (Me₃Si)₂-acetylene·Cu[Me₂N—N═C(CF₃)O], (Me₃Si)₂-acetylene·Ag[Me₂N—N═C(CF₃)O], (Me₃Si)₂-acetylene·Au[Me₂N—N═C(CF₃)O], (Me₃Si)₂-acetylene·Ag[Me₂N—N═C(CF₂CF₃)O], (Me₃Si)₂-acetylene·Cu[MeEtN—N═C(CF₃)O], (Me₃Si)₂-acetylene·Ag[MeEtN—N═C(CF₃)O], (Me₃Si)₂-acetylene·Au[MeEtN—N═C(CF₃)O], (Me₃Si)₂-acetylene·Ag[MeEtN—N═C(CF₂CF₃)O], (Me₃Si)₂-acetylene·Cu[Me₂N—N═C(CF₃)O]₂, Me₃P·Cu[Me₂N—N═C(CF₃)O], Me₃P·Ag[Me₂N—N═C(CF₃)O], Me₃P·Au[Me₂N—N═C(CF₃)O], Me₃P·Ag[Me₂N—N═C(CF₂CF₃)O], Me₃P·Cu[MeEtN—N═C(CF₃)O], Me₃P·Ag[MeEtN—N═C(CF₃)O], Me₃P·Au[MeEtN—N═C(CF₃)O], Me₃P·Ag[MeEtN—N═C(CF₂CF₃)O], Me₃P·Cu[Me₂N—N═C(CF₃)O]₂, Et₃P·Cu[Me₂N—N═C(CF₃)O], Et₃P·Ag[Me₂N—N═C(CF₃)O], Et₃P·Au[Me₂N—N═C(CF₃)O], Et₃P·Ag[Me₂N—N═C(CF₂CF₃)O], Et₃P·Cu[MeEtN—N═C(CF₃)O], Et₃P·Ag[MeEtN—N═C(CF₃)O], Et₃P·Au[MeEtN—N═C(CF₃)O], Et₃P·Ag[MeEtN—N═C(CF₂CF₃)O], Et₃P·Cu[Me₂N—N═C(CF₃)O]₂, (MeO)₃P·Cu[Me₂N—N═C(CF₃)O], (MeO)₃P·Ag[Me₂N—N═C(CF₃)O], (MeO)₃P·Au[Me₂N—N═C(CF₃)O], (MeO)₃P·Ag[Me₂N—N═C(CF₂CF₃)O], (MeO)₃P·Cu[MeEtN—N═C(CF₃)O], (MeO)₃P·Ag[MeEtN—N═C(CF₃)O], (MeO)₃P·Au[MeEtN—N═C(CF₃)O], (MeO)₃P·Ag[MeEtN—N═C(CF₂CF₃)O], (MeO)₃P·Cu[Me₂N—N═C(CF₃)O]₂, Mn[Me₂N—N═C(CF₃)O]₂, Ca[Me₂N—N═C(CF₃)O]₂, Mg[Me₂N—N═C(CF₃)O]₂, Co[Me₂N—N═C(CF₃)O]₂, Sr[Me₂N—N═C(CF₃)O]₂, Zn[Me₂N—N═C(CF₃)O]₂, Cr[Me₂N—N═C(CF₃)O]₂, Ti[Me₂N—N═C(CF₃)O]₂, Cu[MeEtN—N═C(CF₃)O]₂, Mn[MeEtN—N═C(CF₃)O]₂, Ca[MeEtN—N═C(CF₃)O]₂, Mg[MeEtN—N═C(CF₃)O]₂, Co[MeEtN—N═C(CF₃)O]₂, Sr[MeEtN—N═C(CF₃)O]₂, Ni[MeEtN—N═C(CF₃)O]₂, Zn[MeEtN—N═C(CF₃)O]₂, Cr[MeEtN—N═C(CF₃)O]₂, Ti[MeEtN—N═C(CF₃)O]₂, AI[Me₂N—N═C(CF₃)O]₃, Ga[Me₂N—N═C(CF₃)O]₃, In[Me₂N—N═C(CF₃)O]₃, Ti[Me₂N—N═C(CF₃)O]₃, Sc[Me₂N—N═C(CF₃)O]₃, CpTi[Me₂N—N═C(CF₃)O]₂, CpZr[Me₂N—N═C(CF₃)O]₂, CpHf[Me₂N—N═C(CF₃)O]₂, CpV[Me₂N—N═C(CF₃)O]₂, CpSc[Me₂N—N═C(CF₃)O]₂, CpCe[Me₂N—N═C(CF₃)O]₂, CpY[Me₂N—N═C(CF₃)O]₂, CpLa[Me₂N—N═C(CF₃)O]₂, EtAI[Me₂N—N═C(CF₃)O]₂, EtGa[Me₂N—N═C(CF₃)O]₂, EtIn[Me₂N—N═C(CF₃)O]₂, MeAl[Me₂N—N═C(CF₃)O]₂, MeGa[Me₂N—N═C(CF₃)O]₂, MeIn[Me₂N—N═C(CF₃)O]₂, sBuAl[Me₂N—N═C(CF₃)O]₂, sBuGa[Me₂N—N═C(CF₃)O]₂, sBuIn[Me₂N—N═C(CF₃)O]₂, iPrAl[Me₂N—N═C(CF₃)O]₂, iPrGa[Me₂N—N═C(CF₃)O]₂, iPrIn[Me₂N—N═C(CF₃)O]₂, Cp₂Ti[Me₂N—N═C(CF₃)O]₂, Cp₂Zr[Me₂N—N═C(CF₃)O]₂, Cp₂Hf[Me₂N—N═C(CF₃)O]₂, EtCp₂Ti[Me₂N—N═C(CF₃)O]₂, EtCp₂Zr[Me₂N—N═C(CF₃)O]₂, EtCp₂Hf[Me₂N—N═C(CF₃)O]₂, MeCp₂Ti[Me₂N—N═C(CF₃)O]₂, MeCp₂Zr[Me₂N—N═C(CF₃)O]₂, MeCp₂Hf[Me₂N—N═C(CF₃)O]₂, iPrCp₂Ti[Me₂N—N═C(CF₃)O]₂, iPrCp₂Zr[Me₂N—N═C(CF₃)O]₂, iPrCp₂Hf[Me₂N—N═C(CF₃)O]₂, CpTi[Me₂N—N═C(CF₃)O]₃, CpZr[Me₂N—N═C(CF₃)O]₃, CpHf[Me₂N—N═C(CF₃)O]₃, EtCpTi[Me₂N—N═C(CF₃)O]₃, EtCpZr[Me₂N—N═C(CF₃)O]₃, EtCpHf[Me₂N—N═C(CF₃)O]₃, MeCpTi[Me₂N—N═C(CF₃)O]₃, MeCpZr[Me₂N—N═C(CF₃)O]₃, MeCpHf[Me₂N—N═C(CF₃)O]₃, iPrCpTi[Me₂N—N═C(CF₃)O]₃, iPrCpZr[Me₂N—N═C(CF₃)O]₃, or iPrCpHf[Me₂N—N═C(CF₃)O]₃.

8. The method of claim 1, wherein the vapor deposition method is a CVD process including an ALD process.

9. The method of claim 1, wherein a deposition temperature ranges from approximately 50° C. to approximately 600° C.

10. The method of claim 1, further comprising the step of exposing the substrate to a co-reactant.

11. The method of claim 10, wherein the co-reactant is either plasma activated or not plasma activated.

12. The method of claim 10, wherein the co-reactant is an oxygen-containing gas selected from O₂, O₃, H₂O, H₂O₂, NO, N₂O, NO₂, oxygen containing radicals selected from O— or OH—, alcohol, silanols, aminoalcohols, carboxylic acids, para-formaldehyde, carboxylic acids, formic acid, acetic acid, propionic acid, and mixtures thereof.

13. The method of claim 10, wherein the co-reactant is a nitrogen-containing gas selected from H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof.

14. A method for forming a fluorine-doped nickel oxide film on a substrate, the method comprising:
exposing the substrate to a vapor of a metal-containing film-forming composition that contains a fluorinated metal-amidrazonide precursor bis(N,N′-dimethyl-trifluoroacetohydrazonide)nickel(II) [Me₂NN═C(CF₃)O]₂Ni; and
depositing at least part of the fluorinated metal-amidrazonide precursors onto the substrate to form the fluorine-doped nickel oxide film on the substrate through a vapor deposition method.

15. The method of claim 14, further comprising the step of exposing the substrate to a co-reactant O₃.

16. The method of claim 14, wherein the co-reactant is either plasma activated or not plasma activated.

17. A film-forming composition for deposition of a film comprising a fluorinated metal-amidrazonide precursor having the general formula 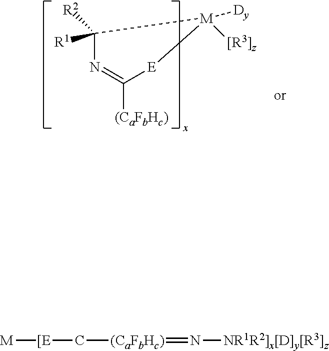
wherein
M is a transition metal or a rare earth element;
E is selected from O, S, Se or Te;
D is a monodentate, bidentate, tridentate, or other polydentate donor with a neutral charge;
CₐF_{b}H_{c} is a fluorinated backbone, wherein a≥1, b≥1, c≥0;
R¹ and R² each is independently selected from an H, a C₁-C₆ linear or branched alkyl group, a C₃-C₆ cyclic alkyl group, a C₂-C₆ linear or branched alkene group, a C₃-C₆ cyclic alkene or aromatic group, wherein any coordinating moieties contain heteroatoms N, O, S;
R³ is selected from an H, a C₁-C₆ linear or branched alkyl group, a C₃-C₆ cyclic alkyl group, a C₂-C₆ linear or branched alkene group, a C₃-C₆ cyclic alkene group, wherein cyclopentadienyl derivatives and any coordinating moieties contain heteroatoms N, O, S;
x is from 1 to 5;
y is from 0 to 5; and
z is from 0 to 5.

18. The composition of claim 17, wherein the fluorinated metal-amidrazonide precursor is bis(N,N′-dimethyl-trifluoroacetohydrazonide)nickel(II) [Me₂NN═C(CF₃)O]₂Ni.

19. The composition of claim 17, wherein the fluorinated metal-amidrazonide precursor is selected from [Me₂N—N═C(CF₃)O]AlEt₂, [Me₂N—N═C(CF₃)O]₂AlEt, [Me₂N—N═C(CF₃)O]₂Cu, [Me₂N—N═C(CF₂H)O]₂Cu, [Me₂N—N═C(CF₃)O]₂Ni, [Me₂N—N═C(CF₂Me)O]₂Ni, [Me₂N—N═C(CF₂Me)O]₂Ni, [Me₂N—N═C(CF₃)O][CH₂C(CH₃)CH₂]Ni, [Me₂N—N═C(CF₂Me)O][CH₂C(CH₃)CH₂]Ni, Ni[Me₂N—N═C(CF₃)O]₂, Li—OC(CF₃)═N—NMe₂, and Na—OC(CF₃)═N—NMe₂.

20. The composition of claim 17, wherein the fluorinated metal-amidrazonide precursor is selected from Cu[Me₂N—N═C(CF₃)O], Ag[Me₂N—N═C(CF₃)O], Au[Me₂N—N═C(CF₃)O], Ag[Me₂N—N═C(CF₂CF₃)O], Cu[MeEtN—N═C(CF₃)O], Ag[MeEtN—N═C(CF₃)O], Au[MeEtN—N═C(CF₃)O], Ag[MeEtN—N═C(CF₂CF₃)O], tmsv·Cu[Me₂N—N═C(CF₃)O], tmsv·Ag[Me₂N—N═C(CF₃)O], tmsv·Au[Me₂N—N═C(CF₃)O], tmsv·Ag[Me₂N—N═C(CF₂CF₃)O], tmsv·Cu[MeEtN—N═C(CF₃)O], tmsv·Ag[MeEtN—N═C(CF₃)O], tmsv·Au[MeEtN—N═C(CF₃)O], tmsv·Ag[MeEtN—N═C(CF₂CF₃)O], tmsv·Cu[Me₂N—N═C(CF₃)O]₂, (Me₃Si)₂-acetylene·Cu[Me₂N—N═C(CF₃)O], (Me₃Si)₂-acetylene·Ag[Me₂N—N═C(CF₃)O], (Me₃Si)₂-acetylene·Au[Me₂N—N═C(CF₃)O], (Me₃Si)₂-acetylene·Ag[Me₂N—N═C(CF₂CF₃)O], (Me₃Si)₂-acetylene·Cu[MeEtN—N═C(CF₃)O], (Me₃Si)₂-acetylene·Ag[MeEtN—N═C(CF₃)O], (Me₃Si)₂-acetylene·Au[MeEtN—N═C(CF₃)O], (Me₃Si)₂-acetylene·Ag[MeEtN—N═C(CF₂CF₃)O], (Me₃Si)₂-acetylene·Cu[Me₂N—N═C(CF₃)O]₂, Me₃P·Cu[Me₂N—N═C(CF₃)O], Me₃P·Ag[Me₂N—N═C(CF₃)O], Me₃P·Au[Me₂N—N═C(CF₃)O], Me₃P·Ag[Me₂N—N═C(CF₂CF₃)O], Me₃P·Cu[MeEtN—N═C(CF₃)O], Me₃P·Ag[MeEtN—N═C(CF₃)O], Me₃P·Au[MeEtN—N═C(CF₃)O], Me₃P·Ag[MeEtN—N═C(CF₂CF₃)O], Me₃P·Cu[Me₂N—N═C(CF₃)O]₂, Et₃P·Cu[Me₂N—N═C(CF₃)O], Et₃P·Ag[Me₂N—N═C(CF₃)O], Et₃P·Au[Me₂N—N═C(CF₃)O], Et₃P·Ag[Me₂N—N═C(CF₂CF₃)O], Et₃P·Cu[MeEtN—N═C(CF₃)O], Et₃P·Ag[MeEtN—N═C(CF₃)O], Et₃P·Au[MeEtN—N═C(CF₃)O], Et₃P·Ag[MeEtN—N═C(CF₂CF₃)O], Et₃P·Cu[Me₂N—N═C(CF₃)O]₂, (MeO)₃P·Cu[Me₂N—N═C(CF₃)O], (MeO)₃P·Ag[Me₂N—N═C(CF₃)O], (MeO)₃P·Au[Me₂N—N═C(CF₃)O], (MeO)₃P·Ag[Me₂N—N═C(CF₂CF₃)O], (MeO)₃P·Cu[MeEtN—N═C(CF₃)O], (MeO)₃P·Ag[MeEtN—N═C(CF₃)O], (MeO)₃P·Au[MeEtN—N═C(CF₃)O], (MeO)₃P·Ag[MeEtN—N═C(CF₂CF₃)O], (MeO)₃P·Cu[Me₂N—N═C(CF₃)O]₂, Mn[Me₂N—N═C(CF₃)O]₂, Ca[Me₂N—N═C(CF₃)O]₂, Mg[Me₂N—N═C(CF₃)O]₂, Co[Me₂N—N═C(CF₃)O]₂, Sr[Me₂N—N═C(CF₃)O]₂, Zn[Me₂N—N═C(CF₃)O]₂, Cr[Me₂N—N═C(CF₃)O]₂, Ti[Me₂N—N═C(CF₃)O]₂, Cu[MeEtN—N═C(CF₃)O]₂, Mn[MeEtN—N═C(CF₃)O]₂, Ca[MeEtN—N═C(CF₃)O]₂, Mg[MeEtN—N═C(CF₃)O]₂, Co[MeEtN—N═C(CF₃)O]₂, Sr[MeEtN—N═C(CF₃)O]₂, Ni[MeEtN—N═C(CF₃)O]₂, Zn[MeEtN—N═C(CF₃)O]₂, Cr[MeEtN—N═C(CF₃)O]₂, Ti[MeEtN—N═C(CF₃)O]₂, AI[Me₂N—N═C(CF₃)O]₃, Ga[Me₂N—N═C(CF₃)O]₃, In[Me₂N—N═C(CF₃)O]₃, Ti[Me₂N—N═C(CF₃)O]₃, Sc[Me₂N—N═C(CF₃)O]₃, CpTi[Me₂N—N═C(CF₃)O]₂, CpZr[Me₂N—N═C(CF₃)O]₂, CpHf[Me₂N—N═C(CF₃)O]₂, CpV[Me₂N—N═C(CF₃)O]₂, CpSc[Me₂N—N═C(CF₃)O]₂, CpCe[Me₂N—N═C(CF₃)O]₂, CpY[Me₂N—N═C(CF₃)O]₂, CpLa[Me₂N—N═C(CF₃)O]₂, EtAI[Me₂N—N═C(CF₃)O]₂, EtGa[Me₂N—N═C(CF₃)O]₂, EtIn[Me₂N—N═C(CF₃)O]₂, MeAl[Me₂N—N═C(CF₃)O]₂, MeGa[Me₂N—N═C(CF₃)O]₂, MeIn[Me₂N—N═C(CF₃)O]₂, sBuAl[Me₂N—N═C(CF₃)O]₂, sBuGa[Me₂N—N═C(CF₃)O]₂, sBuIn[Me₂N—N═C(CF₃)O]₂, iPrAl[Me₂N—N═C(CF₃)O]₂, iPrGa[Me₂N—N═C(CF₃)O]₂, iPrIn[Me₂N—N═C(CF₃)O]₂, Cp₂Ti[Me₂N—N═C(CF₃)O]₂, Cp₂Zr[Me₂N—N═C(CF₃)O]₂, Cp₂Hf[Me₂N—N═C(CF₃)O]₂, EtCp₂Ti[Me₂N—N═C(CF₃)O]₂, EtCp₂Zr[Me₂N—N═C(CF₃)O]₂, EtCp₂Hf[Me₂N—N═C(CF₃)O]₂, MeCp₂Ti[Me₂N—N═C(CF₃)O]₂, MeCp₂Zr[Me₂N—N═C(CF₃)O]₂, MeCp₂Hf[Me₂N—N═C(CF₃)O]₂, iPrCp₂Ti[Me₂N—N═C(CF₃)O]₂, iPrCp₂Zr[Me₂N—N═C(CF₃)O]₂, iPrCp₂Hf[Me₂N—N═C(CF₃)O]₂, CpTi[Me₂N—N═C(CF₃)O]₃, CpZr[Me₂N—N═C(CF₃)O]₃, CpHf[Me₂N—N═C(CF₃)O]₃, EtCpTi[Me₂N—N═C(CF₃)O]₃, EtCpZr[Me₂N—N═C(CF₃)O]₃, EtCpHf[Me₂N—N═C(CF₃)O]₃, MeCpTi[Me₂N—N═C(CF₃)O]₃, MeCpZr[Me₂N—N═C(CF₃)O]₃, MeCpHf[Me₂N—N═C(CF₃)O]₃, iPrCpTi[Me₂N—N═C(CF₃)O]₃, iPrCpZr[Me₂N—N═C(CF₃)O]₃, or iPrCpHf[Me₂N—N═C(CF₃)O]₃.
